(19) United States
(12) Patent Application Publication
(10) Pub. No.: US 2011/0062334 A1
(43) Pub. Date: Mar. 17, 2011

(54) ELECTROMAGNETIC BASED THERMAL SENSING AND IMAGING INCORPORATING DISTRIBUTED MIM STRUCTURES FOR THz DETECTION

(76) Inventor: David Ben-Bassat, Gnai Tikvah (IL)

(21) Appl. No.: 12/881,023

(22) Filed: Sep. 13, 2010

Related U.S. Application Data
(60) Provisional application No. 61/242,321, filed on Sep. 14, 2009.

(51) Int. Cl. H01L 27/14; H01L 31/101; H01L 31/18

(52) U.S. Cl. 250/332; 257/459; 438/98; 257/E31.054; 257/E27.122

(57) ABSTRACT

A novel pixel circuit and multi-dimensional array for receiving and detecting black body radiation in the SWIR, MWIR or LWIR frequency bands. An electromagnetic thermal sensor and imaging system is provided based on the treatment of thermal radiation as an electromagnetic wave. The thermal sensor and imager functions essentially as an electromagnetic power sensor/receiver, operating in the SWIR (200-375 THz), MWIR (60-100 THz), or LWIR (21-38 THz) frequency bands. The thermal pixel circuit of the invention is used to construct thermal imaging arrays, such as 1D, 2D and stereoscopic arrays. Various pixel circuit embodiments are provided including balanced and unbalanced, biased and unbiased and current and voltage sensing topologies. The pixel circuit and corresponding imaging arrays are constructed on a monolithic semiconductor substrate using in a stacked topology. A metal-insulator-metal (MIM) structure provides rectification of the received signal at high terahertz frequencies.

### REFERENCE TO PRIORITY APPLICATION

This application claims priority to U.S. Provisional Application Ser. No. 61/242,321, filed Sep. 14, 2009, entitled “Electro-Magnetic Based Thermal Imaging and related MIM and Semiconductor Structures,” incorporated herein by reference in its entirety.

### FIELD OF THE INVENTION

The present invention relates generally to thermal sensors and imaging systems and more particularly relates to electromagnetic based thermal sensing and imaging.

### BACKGROUND OF THE INVENTION

Thermal radiation is electromagnetic radiation emitted from a material. It is also defined as the transfer of heat energy through empty space by electromagnetic waves. All objects with a temperature above absolute zero radiate energy at a rate equal to their emissivity multiplied by the rate at which energy would radiate from them if they were a black body. If the object is a black body in thermodynamic equilibrium, the thermal radiation is termed black-body radiation. The emitted wave frequency of the black body thermal radiation is described by a probability distribution depending only on temperature, and for a genuine black body in thermodynamic equilibrium, is given by Planck's law of radiation. No medium is necessary for radiation to occur, for it is transferred by electromagnetic waves. Thermal radiation takes place even in and through a perfect vacuum. For instance, the energy from the Sun travels through the vacuum of space before warming the earth. Radiation is the only form of heat transfer that can occur in the absence of any form of medium (i.e. through a vacuum).

Thermal radiation is a direct result of the movements of atoms and molecules in a material. The radiation is due to the heat of the material, the characteristics of which depend on its temperature. Thermal radiation is generated when heat from the movement of charges in the material is converted to electromagnetic radiation. For example, sunshine, or solar radiation, is thermal radiation from the extremely hot gases of the Sun, and this radiation heats the Earth. Since the atoms and molecules in a material are composed of charged particles (i.e. protons and electrons), their movements result in the emission of electromagnetic radiation, which carries energy away from the surface. At the same time, the surface is constantly bombarded by radiation from its surroundings, resulting in the transfer of energy to the surface. Since the amount of emitted radiation increases with increasing temperature, a net transfer of energy from higher temperatures to lower temperatures results.

Both reflectivity and emissivity of all bodies is wavelength dependent. The temperature determines the wavelength distribution of the electromagnetic radiation as limited in intensity by Planck's law of black-body radiation. For any body the reflectivity depends on the wavelength distribution of incoming electromagnetic radiation and therefore the temperature of the source of the radiation. The emissivity depends on the wave length distribution and therefore the temperature of the body itself.

Infrared (IR) light is electromagnetic radiation with a wavelength between 0.7 and 300 μm, which equates to a frequency range between approximately 1 and 430 terahertz (THz). IR wavelengths are longer than that of visible light, but shorter than that of terahertz radiation microwaves.

IR radiation can be subdivided into three sections. In the first, short-wavelength infrared (SWIR) has a wavelength of 0.8 to 1.5 μm which corresponds to a frequency of 200 to 375 THz. Middle-wavelength infrared (MWIR) has a wavelength of 3 to 5 μm which corresponds to a frequency of 60 to 100 THz. Long-wavelength infrared (LWIR) has a wavelength of 8 to 14 μm which corresponds to a frequency of 21 to 38 THz. The LWIR region is the “thermal imaging” region, in which prior art thermal sensors can obtain a completely passive picture of the outside world based on thermal emissions only, requiring no external light or thermal source such as the sun, moon or infrared illuminator.

It can be shown that a black body in a temperature of 300° K radiates most of its energy in the wavelength band of 8-14 μm. This, combined with an exceptional transmission coefficient of the earth atmosphere in the same band makes it a useful band for thermal imaging. A plot of atmospheric transmission and black body radiation spectrum at 300° K temperature is shown in FIG. 1. There is a clear correlation between the peak radiation in the transmission window of 8-14 μm indicated as “Longwave Infrared”.

Prior art LWIR thermal imagers are manufactured today using one of two technologies: cooled or uncooled. Cooled imagers function as photon detectors and work by sensing the thermal photonic flux of energy incident on them based on the photo-electric effect. Since thermal photons have very little energy per photon, special materials with exceptionally low band gaps are used for sensing. A major disadvantage, however, is that these sensors are very expensive to manufacture. Another disadvantage is that they require cryogenic cooling to 77° K, for example, to function well. Cooling is required to minimize self-imposed thermal noise, as generated by the sensors.

Uncooled imagers are essentially thermal sensing imagers. They absorb the LWIR energy, use it to heat a pixel up and measure the induced electrical change due to the heating. The most common uncooled sensors are bolometers, where each pixel is actually a resistor, whose resistance changes over temperature. Other types of prior art uncooled imagers use pyroelectric, gas expansion and thermopile technologies. A disadvantage of uncooled imagers, however, it that they typically exhibit low sensitivity, and also require complex, expensive and difficult to construct Micro Electro Mechanical Systems (MEMS) production technologies. Furthermore, they require vacuum packaging to work well which is required to thermally isolate one pixel from the adjacent pixels.

It would therefore be desirable to have a thermal imaging system that is capable of imaging in the long-wavelength infrared (LWIR) region that does not suffer the disadvantages of the prior art imaging systems. The thermal imaging system should preferably be able to provide thermal images without requiring the costly cooling or MEMS structures of prior art imagers.

### SUMMARY OF THE INVENTION

The present invention is a novel pixel circuit and multi-dimensional array for receiving and detecting black body radiation in the SWIR, MWIR or LWIR frequency bands. The invention provides an electromagnetic thermal sensor and imaging system based on the treatment of thermal radiation as an electromagnetic wave. In essence, the thermal sensor and imager is an electromagnetic power sensor/receiver, operating in the SWIR (200-375 THz), MWIR (60-100 THz), or LWIR (21-38 THz) frequency bands. The thermal pixel circuit of the invention is used to construct thermal imaging arrays, such as 1D, 2D and stereoscopic arrays.

Various pixel circuit embodiments are provided including balanced and unbalanced, biased and unbiased and current and voltage sensing topologies. The pixel circuit and corresponding imaging arrays are constructed on a monolithic semiconductor substrate used in a stacked topology. A low frequency backend readout circuit is fabricated on the substrate while the high frequency sensor circuit is fabricated stacked on top of the backend circuit. A metal-insulator-metal (MIM) structure in the front end circuit provides rectification of the received signal at high terahertz frequencies.

Use of the electromagnetic approach to thermal imaging and the resultant pixel circuit of the invention provides numerous advantages, including (1) no cooling of the thermal sensor is required since the noise figure of the system is almost constant over temperature; (2) no MEMS technology is required as the pixel circuit is fabricated on a monolithic semiconductor substrate using standard IC processes; (3) no vacuum packaging is required as is the case with prior art thermal sensors; and (4) the sensitivity of the thermal sensor is potentially higher than of uncooled sensors, because detection is performed directly on the received signal, rather than on a signal from a second-stage conversion.

There is thus provided in accordance with the invention, a metal-insulator-metal (MIM) structure for terahertz detection in a thermal sensor comprising a first metal layer fabricated on a monolithic semiconductor substrate, an insulator layer fabricated over the first metal layer, a second metal layer fabricated over the insulator layer, wherein the insulator layer is sufficiently thin for tunneling to occur between the first metal layer and second metal layer and wherein as a result of the tunneling, the MIM structure functions as a rectifier when excited with an input signal at terahertz frequencies so as to generate a rectified signal therefrom.

There is also provided in accordance with the invention, a thermal sensor adapted to be fabricated on a monolithic semiconductor substrate comprising an antenna element operative to absorb black body radiation at terahertz (THz) frequencies and convert it to an electrical signal, an impedance matching circuit coupled to the antenna element, a metal-insulator-metal (MIM) structure operative to rectify the output of the impedance matching network and wherein the MIM structure comprises a first metal layer, an insulator layer fabricated over the first metal layer, a second metal layer fabricated over the insulator layer, wherein the insulator layer is sufficiently thin for tunneling to occur between the first metal layer and second metal layer, and wherein as a result of the tunneling, the MIM structure functions as a rectifier when excited with the terahertz frequency output of the impedance matching network so as to generate a rectified signal therefrom.

There is further provided in accordance with the invention, a method of constructing a thermal sensor on a monolithic semiconductor substrate, the method comprising fabricating an antenna element on the substrate, the antenna element operative to absorb black body radiation at terahertz (THz) frequencies and convert it to an electrical signal, fabricating a first metal layer of a metal-insulator-metal (MIM) structure on the substrate, fabricating an insulating layer over the first metal layer, fabricating a second metal layer over the insulating layer, wherein the insulator layer is fabricated sufficiently thin for tunneling to occur between the first metal layer and second metal layer such that the MIM structure functions as a rectifier when excited with terahertz frequency energy absorbed by the antenna and to generate a rectified signal therefrom and wherein the MIM structure is configured and shaped using distributed design techniques such that a first distributed reactance is generated that at least partially cancels out a second distributed reactance inherent in the MIM structure.

There is also provided in accordance with the invention, a thermal imager comprising an antenna element operative to absorb black body radiation at terahertz (THz) frequencies and convert it to an electrical signal and an impedance matching circuit coupled to the antenna element, the impedance matching circuit operative to match the complex impedance of the antenna element to a high impedance load, a metal-insulator-metal (MIM) structure coupled to the load, the MIM structure operative to perform non-coherent rectification of the signal generated by the antenna element, a sense circuit coupled to the MIM structure, the sense circuit operative to generate a single pixel measurement of the black body radiation power absorbed by the antenna element and a display subsystem operative to present to a user information corresponding to the single pixel measurement.

### BRIEF DESCRIPTION OF THE DRAWINGS

The invention is herein described, by way of example only, with reference to the accompanying drawings, wherein:

FIG. 1 is a plot of atmospheric transmission and black body radiation spectrum at 300° K temperature;

FIG. 2 is a schematic diagram illustrating a representative pixel circuit;

FIG. 3 is a schematic diagram illustrating an example biased, unbalanced topology, current sense pixel circuit;

FIG. 4 is a schematic diagram illustrating an example unbiased, unbalanced topology, current sense pixel circuit;

FIG. 5 is a schematic diagram illustrating an example biased, unbalanced topology, voltage sense pixel circuit;

FIG. 6 is a schematic diagram illustrating an example unbiased, unbalanced topology, voltage sense pixel circuit;

FIG. 7 is a schematic diagram illustrating an example biased, balanced topology, current sense pixel circuit;

FIG. 8 is a schematic diagram illustrating an example unbiased, balanced topology, current sense pixel circuit;

FIG. 9 is a schematic diagram illustrating an example biased, balanced topology, voltage sense pixel circuit;

FIG. 10 is a schematic diagram illustrating an example unbiased, balanced topology, voltage sense pixel circuit;

FIG. 11 is a diagram illustrating an example Vivaldi antenna for use with THz black body radiation;

FIG. 12 is a diagram illustrating an example quarter wavelength transformer followed by an LC network;

FIG. 13 is a schematic diagram illustrating the equivalent electrical circuit of the antenna and load resistor and small-signal model of the rectifier;

FIG. 14 is a schematic diagram illustrating the Norton equivalent electrical circuit of the antenna and load resistor and small-signal model of the rectifier;

FIG. 15 is a plot illustrating an example tunnel junction MIM I(V) curve;

FIG. 16 is a schematic diagram illustrating an example monolithic CMOS implementation of the thermal pixel front and back end circuits;

FIG. 17 is a diagram illustrating an example one dimensional thermal pixel array;

FIG. 18 is a diagram illustrating an example two dimensional thermal pixel array;

FIG. 19 is a schematic diagram illustrating an example unbalanced, biased topology, current sense pixel circuit;

FIG. 20 is a schematic diagram illustrating an example unbalanced, biased topology, voltage sense pixel circuit;

FIG. 21 is a schematic diagram illustrating an example unbalanced, unbiased topology, current sense pixel circuit;

FIG. 22 is a schematic diagram illustrating an example unbalanced, unbiased topology, voltage sense pixel circuit;

FIG. 23 is a schematic diagram illustrating an example differential, biased topology, current sense pixel circuit;

FIG. 24 is a schematic diagram illustrating an example differential, biased topology, voltage sense pixel circuit;

FIG. 25 is a schematic diagram illustrating an example differential, unbiased topology, current sense pixel circuit;

FIG. 26 is a schematic diagram illustrating an example differential, unbiased topology, voltage sense pixel circuit;

FIG. 27 is a diagram illustrating an example differential quarter wavelength co-planar transformer;

FIG. 28 is a flow diagram illustrating an example monolithic integrated circuit fabrication method;

FIG. 29 is a diagram illustrating a silicon IC wafer with the backend readout circuit implemented on it;

FIG. 30 is a diagram illustrating the fabrication step of deposition of a thin metal layer on the IC wafer;

FIG. 31 is a diagram illustrating the fabrication step of deposition of a thick insulating layer on top of the metal layer;

FIG. 32 is a diagram illustrating the step of depositing a metal layer on the insulating layer to fabricate the antenna and other high frequency components of the thermal pixel circuit;

FIG. 33 is a diagram illustrating the fabrication step of antenna oxidation to create a thin insulating layer;

FIG. 34 is a diagram illustrating the fabrication step of additional deposition of metal to create the MIM junction and DC capacitor;

FIG. 35 is a diagram illustrating a silicon IC wafer with the differential backend readout circuit implemented on it;

FIG. 36 is a diagram illustrating the fabrication step of deposition of a thin metal layer on the IC wafer;

FIG. 37 is a diagram illustrating the fabrication step of deposition of a thick insulating layer on top of the metal layer;

FIG. 38 is a diagram illustrating the step of depositing of a metal layer on the insulating layer to fabricate differential sensor components;

FIG. 39 is a diagram illustrating the fabrication step of deposition of a thin insulating film layer to build a MIM structure;

FIG. 40 is a diagram illustrating the fabrication step of deposition of a second metal layer to complete the MIM structure;

FIG. 41 is a diagram illustrating an example metal-insulator-metal (MIM) structure in more detail;

FIG. 42 is a schematic diagram illustrating an example lumped RC model of the MIM junction;

FIG. 43 is a schematic diagram illustrating an example MIM structure and the lumped MIM equivalent circuit corresponding thereto;

FIG. 44 is a schematic diagram illustrating an example MIM structure and the distributed MIM equivalent circuit corresponding thereto;

FIG. 45 is a diagram illustrating an example microstrip transmission line;

FIG. 46 is a diagram illustrating a first example inductive MIM structure;

FIG. 47 is a diagram illustrating a second example inductive MIM structure having a spiral shape;

FIG. 48 is diagram illustrating an example two step quarter wavelength transformer; and

FIG. 49 is a high level block diagram illustrating an example thermal imaging camera device.

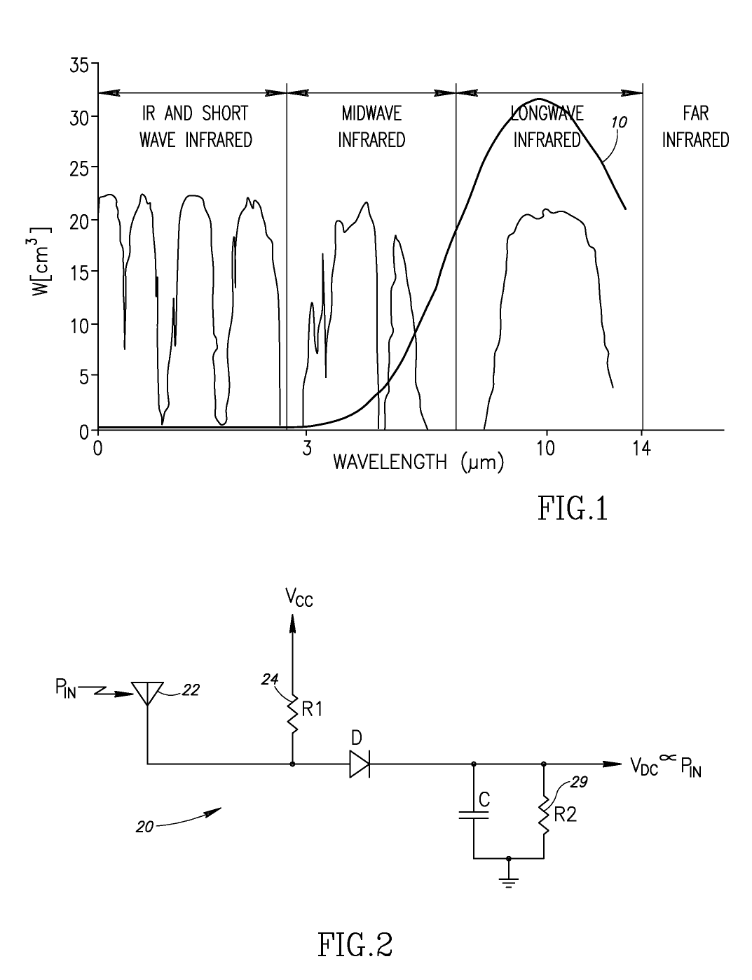

### DETAILED DESCRIPTION OF THE INVENTION

### Notation Used Throughout

The following notation is used throughout this document.

| Term | Definition |
|---|---|
| AC | Alternatively Current |
| ADC | Analog to Digital Converter |
| ALD | Atomic Layer Deposition |
| CCD | Charge Coupled Device |
| CMOS | Complimentary Metal Oxide Semiconductor |
| CMRR | Common Mode Rejection Ratio |
| DC | Direct Current |
| IC | Integrated Circuit |
| IR | Infrared |
| LNA | Low Noise Amplifier |
| LWIR | Long-wavelength Infrared |
| MEMS | Micro Electro Mechanical Systems |
| MIM | Metal-Insulator-Metal |
| MWIR | Middle-wavelength Infrared |
| RF | Radio Frequency |
| SNR | Signal to Noise Ratio |
| SWIR | Short-wavelength Infrared |
| TIA | Tans-Impedance Amplifier |
| VA | Voltage Amplifier |

### DETAILED DESCRIPTION OF THE INVENTION

The present invention is a novel pixel circuit and multi-dimensional array for receiving and detecting black body radiation in the SWIR, MWIR or LWIR frequency bands. The invention provides an electromagnetic thermal sensor and imaging system based on the treatment of thermal radiation as an electromagnetic wave. In essence, the thermal sensor and imager is an electromagnetic power sensor/receiver, operating in the SWIR (200-375 THz), MWIR (60-100 THz), or LWIR (21-38 THz) frequency bands. The thermal pixel circuit of the invention is used to construct thermal imaging arrays, such as 1D, 2D and stereoscopic arrays.

To achieve the desired goal of providing an uncooled thermal sensor that does not require vacuum or MEMS technology, black body radiation is treated as any other electromagnetic radiation. An antenna, tuned and configured to absorb black body radiation, converts the electromagnetic radiation into an electrical signal. This electrical signal is then rectified, amplified and processed for readout to downstream processing, such as image processing for display to a user.

Note that throughout this document, the term thermal radiation is defined as electromagnetic radiation emitted from a material which is due to the temperature of the material. If the object is a black body in thermodynamic equilibrium, the radiation is referred to as black-body radiation.

The term antenna element is intended to refer to the actual radiating element that is capable of receiving electromagnetic radiation and generating an electrical signal therefrom. It does not necessarily also include a tuning circuit which is typically separate from the antenna element. In one embodiment, the antenna element comprises an antenna fabricated on a monolithic semiconductor substrate.

Electromagnetic Based Thermal Sensor

As described supra, prior art cooled thermal sensors treat black body radiation as a photonic flux. Prior art uncooled thermal sensors treat black body radiation as a heat source. The thermal sensor of the present invention treats black body radiation as any other electromagnetic energy, such as radio waves (RF), microwaves, x-rays, etc. Considering modern physics theory that explains the nature of light including the notion of wave-particle duality, as described by Albert Einstein in the early 1900s, allows light (as well as other types of electromagnetic radiation) to be treated as either a photonic flux or an electromagnetic wave.

By considering thermal (i.e. black body) radiation as any other type of electromagnetic energy, electromagnetic theory as proposed by James Maxwell can be applied to detect and analyze thermal radiation. Furthermore, an antenna can be used to convert this electromagnetic radiation directly into an electrical signal. The antenna thus serves as a ‘transducer’ operative to convert the electromagnetic radiation into electric power (voltage and current). By measuring the power or amplitude of the electrical signal generated by the antenna at its antenna port, the longwave infrared (LWIR) power or other type of radiation power absorbed by the antenna can be deduced. Thus, relying on the theory of the duality of light, thermal radiation is treated as any other electromagnetic radiation and antenna is used to sense this radiation.

Representative and Example Pixel Circuits

A schematic diagram illustrating a representative pixel circuit is shown in FIG. 2.

The circuit, generally referenced 20, comprises an antenna 22, matching resistor R₁ (24) connected to V_{CC}, rectifier D, capacitor C and load resistor R₂ (29). The antenna is configured to receive and absorb the input thermal radiation Pᵢₙ[W] incident on it, for example LWIR thermal radiation having a wavelength 8 to 14 μm which corresponds to the frequency range of 21 to 37.5 THz. In this example, the antenna is configured to have a center frequency F_{c} of 30 THz and a 3 dB bandwidth of +/−5 THz.

Matching resistor R₁ is set to be equal to the impedance of the antenna, i.e. R₁=Zₐₙₜₑₙₙₐ. The voltage generated at the input to the rectifier D can be expressed as V=Pᵢₙ²/R₁. The rectified output voltage V_{dc}[V] developed across the capacitor C and load resistor R₂ is proportional to the input thermal power incident on the antenna, i.e. V_{dc}[V]∝Pᵢₙ[W].

Considering the topology of the pixel circuit of FIG. 2, several embodiments of this circuit can be constructed including topologies variations such as where the receiving link can be either symmetrical (i.e. balanced or differential) or asymmetrical (i.e. unbalanced). In addition, some embodiments of the pixel circuit may comprise either current sensing (i.e. series sensing) or voltage sensing (i.e. parallel sensing). Further, some embodiments of the pixel circuit may apply an unbiased topology or a topology in which DC biasing is employed. The eight pixel circuits, representing example combinations of the above variations, are described hereinbelow. It is appreciated by one skilled in the art that various other topologies may be constructed without departing from the scope of the invention. In an alternative embodiment, matching resistor R₁ can be removed by tuning the rectifier D to directly match the impedance of the antenna.

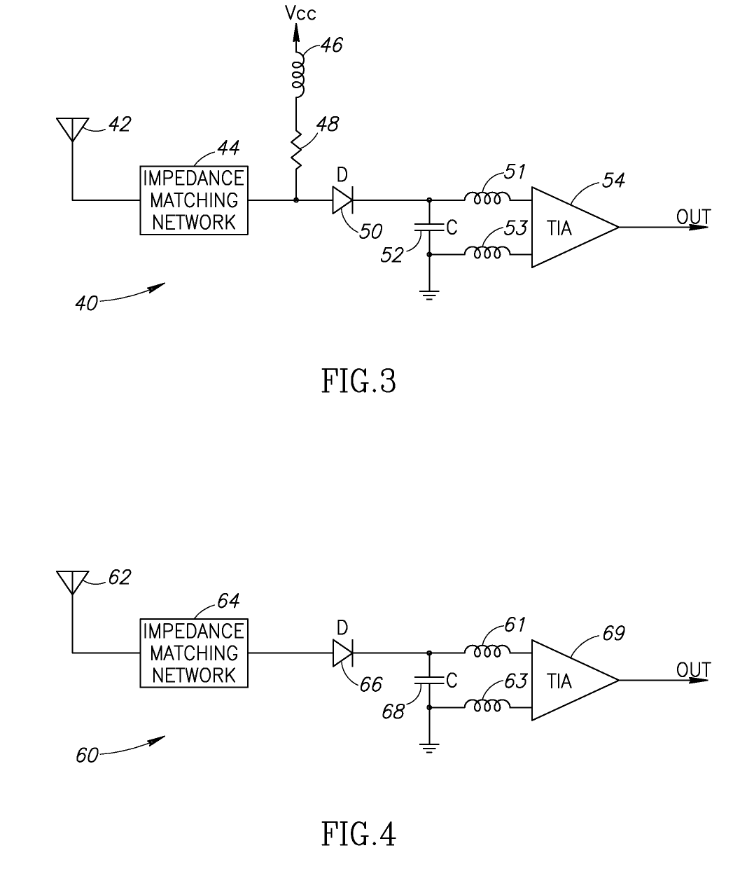

A schematic diagram illustrating an example biased, unbalanced topology, current sense pixel circuit is shown in FIG. 3. The pixel circuit, generally referenced 40, comprises an antenna 42 configured for receiving and absorbing black body radiation at terahertz frequencies, impedance matching network 44, biasing resistor 48, inductor 46 tied to V_{CC}, rectifier D 50, capacitor C 52, series inductors 51, 53 and current sense circuit 54 (e.g., trans-impedance amplifier (TIA)). In operation, the antenna 42 receives and absorbs thermal radiation and converts it to an electrical signal which is input to the impedance matching network 44. The output of the impedance matching network is rectified by rectifier (e.g., diode) 50. The current output charges capacitor C 52. The capacitor is constantly being discharged by TIA 54. Discharge current is amplified by trans-impedance amplifier 54. The sense output signal generated by the TIA represents the output thermal pixel.

A schematic diagram illustrating an example unbiased, unbalanced topology, current sense pixel circuit is shown in FIG. 4. The pixel circuit, generally referenced 60, comprises an antenna 62 configured for receiving and absorbing black body radiation at terahertz frequencies, impedance matching network 64, rectifier D 66, capacitor C 68, series inductors 61, 63 and current sense circuit 69 (e.g., trans-impedance amplifier (TIA)). In operation, the antenna 62 receives and absorbs thermal radiation and converts it to an electrical signal which is input to the impedance matching network 64. The output of the impedance matching network is rectified by rectifier (e.g., diode) 66. The current output charges capacitor C 68. The capacitor is constantly being discharged by TIA 69. Discharge current is amplified by trans-impedance amplifier 69. The sense output signal generated by the TIA represents the output thermal pixel.

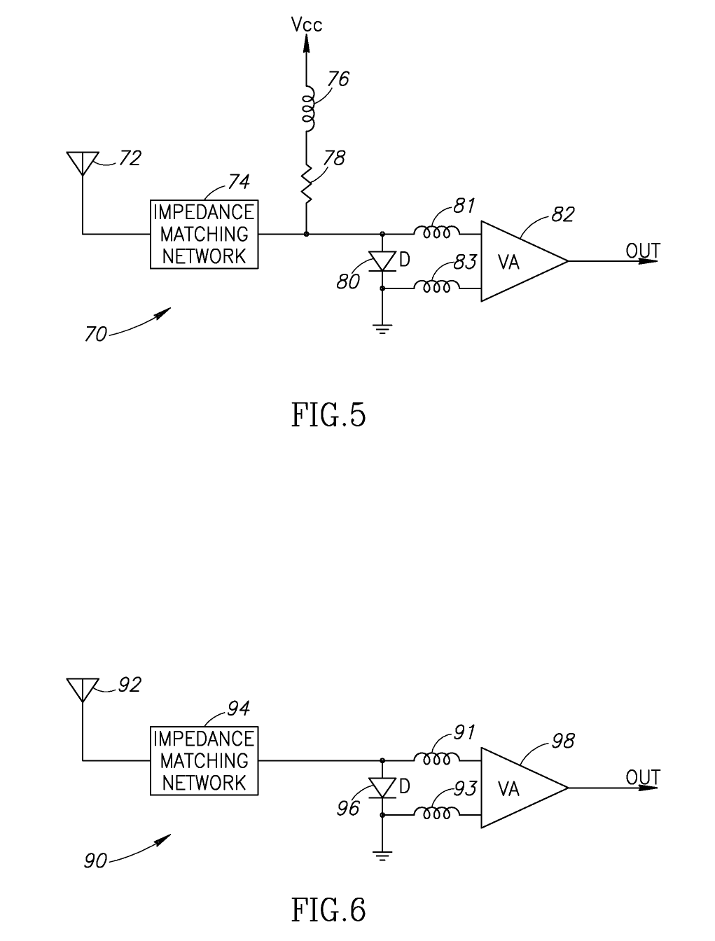

A schematic diagram illustrating an example biased, unbalanced topology, voltage sense pixel circuit is shown in FIG. 5. The pixel circuit, generally referenced 70, comprises an antenna 72 configured for receiving and absorbing black body radiation at terahertz frequencies, impedance matching network 74, biasing resistor 78, inductor 76 tied to V_{CC}, rectifier D 80, series inductors 71, 73 and voltage sense circuit (voltage amplifier (VA)) 82. In operation, the antenna 72 receives and absorbs thermal radiation and converts it to an electrical signal which is input to the impedance matching network 74. The output of the impedance matching network is rectified by rectifier (e.g., diode) 80. Rectification generates DC voltage across rectifier D. The voltage developed across the rectifier is sensed and amplified by voltage amplifier 82. The sense output signal generated by the voltage amplifier represents the output thermal pixel.

A schematic diagram illustrating an example unbiased, unbalanced topology, voltage sense pixel circuit is shown in FIG. 6. The pixel circuit, generally referenced 90, comprises an antenna 92 configured for receiving and absorbing black body radiation at terahertz frequencies, impedance matching network 94, rectifier 96, series inductors 91, 93 and voltage sense circuit (voltage amplifier (VA)) 98. In operation, the antenna 92 receives and absorbs thermal radiation and converts it to an electrical signal which is input to the impedance matching network 94. The output of the impedance matching network is rectified by rectifier (e.g., diode) 96. Rectification generates DC voltage across rectifier D. The voltage developed across the rectifier is sensed and amplified by voltage amplifier 98. The sense output signal generated by the voltage amplifier represents the output thermal pixel.

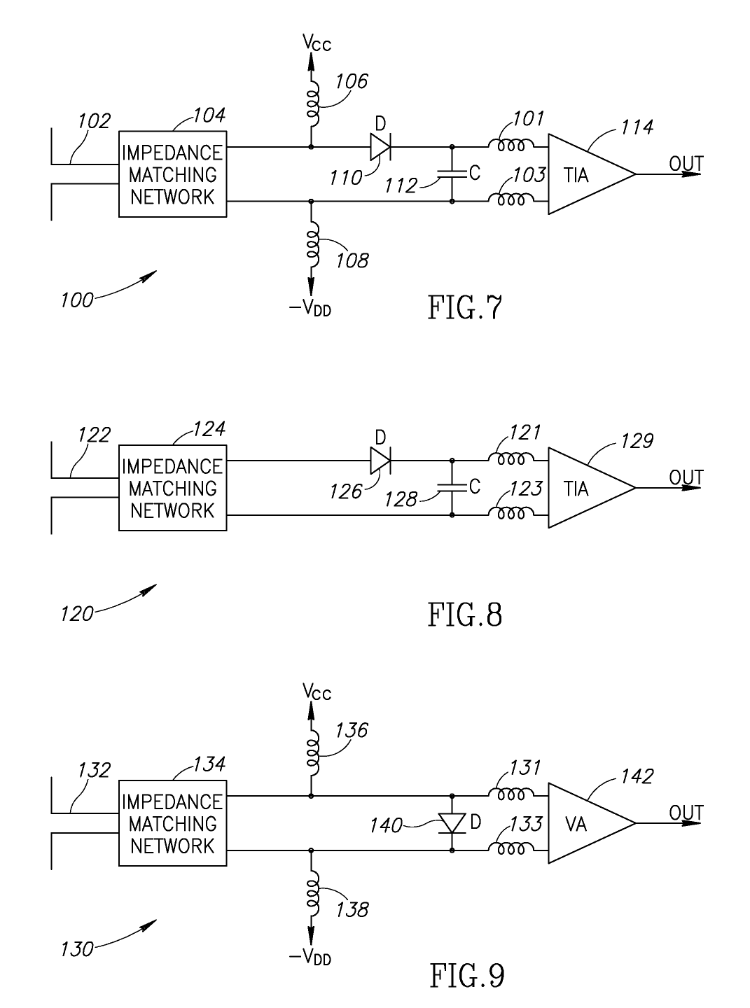

A schematic diagram illustrating an example biased, balanced (i.e. differential) topology, current sense pixel circuit is shown in FIG. 7. The pixel circuit, generally referenced 100, comprises an antenna 102 with a differential interface configured for receiving and absorbing black body radiation at terahertz frequencies, differential impedance matching network 104, inductor 106 tied to V_{CC}, inductor 108 tied to −V_{DD}, rectifier D 110, capacitor C 112, series inductors 101, 103 and current sense circuit 114 (e.g., trans-impedance amplifier (TIA)). In operation, the antenna 102 receives and absorbs thermal radiation and converts it to a balanced electrical signal which is input to differential impedance matching network 104. The output of the impedance matching network is rectified by rectifier (e.g., diode) 110. The current output charges capacitor C 112. The capacitor is constantly being discharged by TIA 114. Discharge current is amplified by trans-impedance amplifier 114. The sense output signal generated by the TIA represents the output thermal pixel.

A schematic diagram illustrating an example unbiased, balanced (i.e. differential) topology, current sense pixel circuit is shown in FIG. 8. The pixel circuit, generally referenced 120, comprises an antenna 122 with a differential interface configured for receiving and absorbing black body radiation at terahertz frequencies, differential impedance matching network 124, rectifier D 126, capacitor C 128, series inductors 131, 133 and current sense circuit 129 (e.g., trans-impedance amplifier (TIA)). In operation, the antenna 122 receives and absorbs thermal radiation and converts it to a balanced electrical signal which is input to differential impedance matching network 124. The output of the impedance matching network is rectified by rectifier (e.g., diode) 126. The current output charges capacitor C 128. The capacitor is constantly being discharged by TIA 129. Discharge current is amplified by trans-impedance amplifier 129. The sense output signal generated by the TIA represents the output thermal pixel.

A schematic diagram illustrating an example biased, balanced (i.e. differential) topology, voltage sense pixel circuit is shown in FIG. 9. The pixel circuit, generally referenced 130, comprises an antenna 132 with a differential interface configured for receiving and absorbing black body radiation at terahertz frequencies, differential impedance matching network 134, inductor 136 tied to V_{CC}, inductor 138 tied to −V_{DD}, rectifier 140, series inductors 151, 153 and voltage sense circuit 142 (e.g., voltage amplifier (VA)). In operation, the antenna 132 receives and absorbs thermal radiation and converts it to a balanced electrical signal which is input to differential impedance matching network 134. The output of the impedance matching network is rectified by rectifier (e.g., diode) 140. Rectification generates DC voltage across rectifier. The voltage developed across rectifier 140 is sensed and amplified by voltage amplifier 142. The sense output signal generated by the voltage amplifier represents the output thermal pixel.

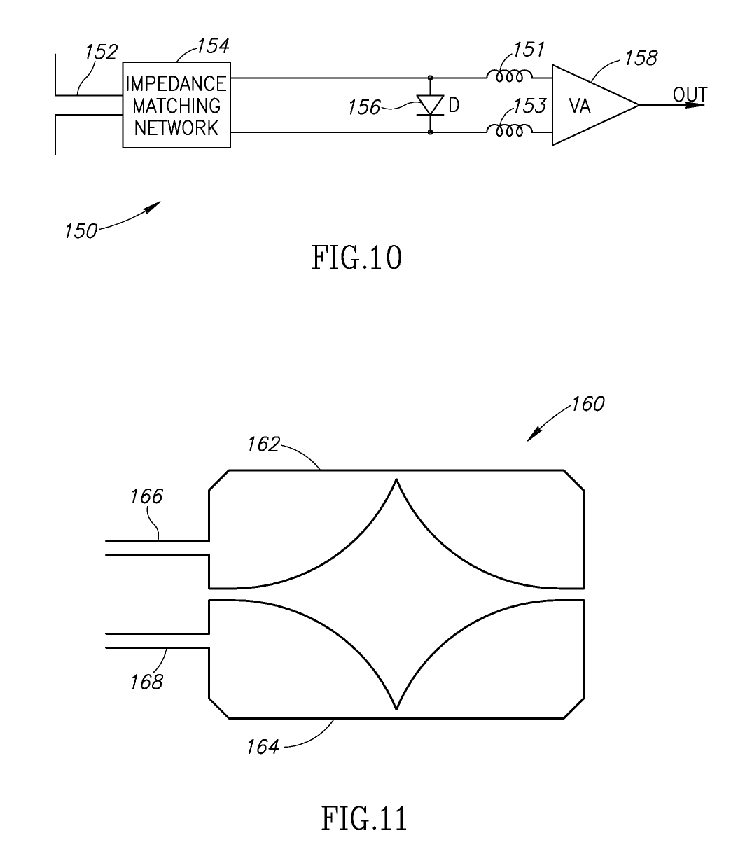

A schematic diagram illustrating an example unbiased, balanced (i.e. differential) topology, voltage sense pixel circuit is shown in FIG. 10. The pixel circuit, generally referenced 150, comprises an antenna 152 with a differential interface configured for receiving and absorbing black body radiation at terahertz frequencies, differential impedance matching network 154, rectifier 156, series inductors L and voltage sense circuit 158 (e.g., voltage amplifier (VA)). In operation, the antenna 152 receives and absorbs thermal radiation and converts it to a balanced electrical signal which is input to differential impedance matching network 154. The output of the impedance matching network is rectified by rectifier (e.g., diode) 156. Rectification generates DC voltage across rectifier. The voltage developed across rectifier 156 is sensed and amplified by voltage amplifier 158. The sense output signal generated by the voltage amplifier represents the output thermal pixel.

It is noted that the example circuits presented herein are configured to have an operating band in the LWIR, MWIR or SWIR range. For example, consider LWIR which have a wave length in the range of 8-14 μm. Taking into account the speed of light in vacuum, this radiation can also be regarded as an RF signal with a frequency in the range of 21-37.5 THz. It is appreciated that the same mechanism described herein can be applied to other bands such as MWIR and SWIR.

Antenna Characteristics

In one example embodiment, the antenna of the pixel circuit (FIGS. 3 to 10 for example) is configured to have a center frequency of operation in the vicinity of 30 THz. Such an antenna corresponds to a wavelength of approximately 10 μm. Numerous antenna topologies are suitable for use with the pixel circuit of the present invention. As an example, the antenna comprises a dipole antenna, whose size is approximately 5 μm, which exhibits optimal absorption of energy in this frequency band. Other antennas with the same order of magnitude of size (e.g., patch, monopole, inverted-F, differential, etc.) are also applicable and provide sufficient performance.

Note that it is preferable that the bandwidth of the antenna be as wide as possible. For example, optimal antenna bandwidth preferably covers the entire band of 21.5 to 37.5 THz. Further, the antenna may comprise a differential antenna (e.g., loop, dipole, etc.) or non-differential (e.g., patch, inverted-F, etc.).

A diagram illustrating an example Vivaldi antenna for use with THz black body radiation is shown in FIG. 11. The antenna, generally referenced 160, comprises two portions 162, 164 separated from each other and designed to have a diamond shaped open space between each portion. Each portion 162, 164 comprises a lead wire 166, 168, respectively. Such an antenna is an example of a wideband Vivaldi antenna, adapted to be implemented on a silicon substrate. Note that the antenna may be constructed using standard metal payer IC processing technology. It is noted that Vivaldi type antennas are particularly applicable for the pixel circuit of the present invention because (1) they are planar antennas which are well suited to being implemented in a single plane; and (2) they are very wideband antennas and provide good performance for the pixel circuit.

Regarding directivity and gain of the antenna, it is noted that it is typical that remote temperature sensing and imaging applications involve the use of optics to aid in focusing the image. The sensor is typically placed at the focal plane of the optics. Translating this into antenna terms means that the antenna receives energy only from a specific sector, as defined by the particular features of the optics. This fact is utilized to enhance system performance by using directional antennas. Examples of directional antennas include, but are not limited to, a patch antenna, log-periodic antenna and Vivaldi antenna. Other types of directional antennas may also be used and are applicable to the pixel circuit of the present invention.

In an alternative embodiment, the pixel circuit comprises an antenna array. Such an array is larger in area than a single antenna but exhibits much better efficiency and gain (i.e. directivity). An antenna array is the electromagnetic equivalent of a larger and more sensitive pixel. Note that the antenna array may comprise an array of patch antennas, slot antennas, dipole antennas, Vivaldi antennas or any other suitable type of antenna. Antenna arrays may also comprise combinations of different types of antennas. Combining different antenna types achieves overall better efficiency, as each type has its own polarity. The combination of different types allows all applicable polarities to be covered.

In regards to polarization, it is noted that antennas, by definition, are polarized elements. Given that the radiation is non-coherent and non-polarized, a simple linearly-polarized antenna would yield significant losses (e.g., 50%) since a significant portion of the energy is received by the antenna. Therefore, to optimize system performance, the antenna used in the pixel circuit is configured to cover as many modes as possible of polarization.

In an example embodiment presented herein, the antenna is loaded by two elements in parallel, namely a load resistor R and a rectifying element D. In small signal analysis, rectifying element D can also be approximated as a resistor R_{D}, as described in more detail infra. Considering the combination of R and D, the equivalent load is denoted R_{eq}=R∥R_{D}. Note that in an alternative embodiment, the rectifying element is tuned to reflect a small-signal impedance that is the complex conjugate match of the antenna impedance. This can be achieved either directly or through an appropriate impedance matching network. In such cases, the load resistor R is not required to serve as part of the antenna load.

Impedance Matching Network

In one example embodiment, the output of the antenna (or antenna array) is an electrical signal in the frequency band of 21-37.5 THz (other antennas may generate an electrical signal in other frequency bands such as MWIR or SWIR). Considering a pixel circuit topology based on voltage signal rectification, it is desirable to obtain the largest voltage swing possible out of the antenna. An impedance matching network is placed between antenna port and the load to aid in matching the complex impedance of the antenna to a high impedance load.

In an example embodiment, the impedance matching network is based on lumped passive elements (e.g., inductors, capacitors and transformers), distributed elements (e.g., transmission lines and stubs) or a combination of lumped and distributed elements. It is appreciated by one skilled in the electrical arts that numerous well-known techniques and tools can be used to design impedance matching networks suitable for use with the present invention.

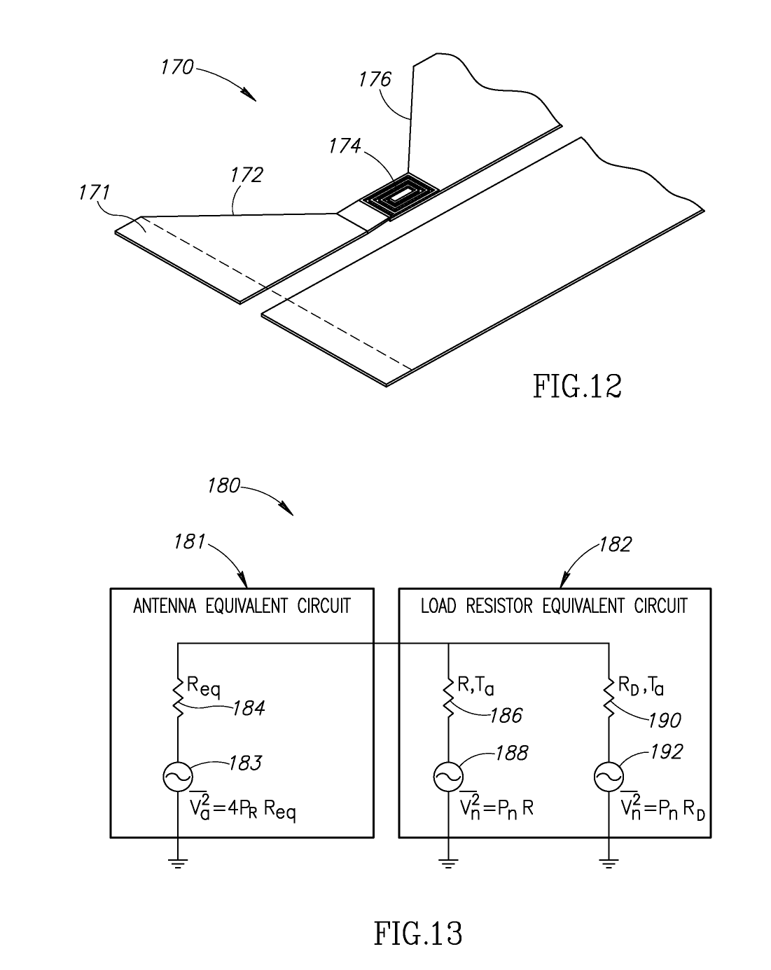

A diagram illustrating an example quarter wavelength transformer followed by an LC network is shown in FIG. 12. The transformer, generally referenced 170, is an example of a quarter-wavelength distributed impedance transformer, comprising elements 171, 172, 174, 176 followed by a half lumped distributed L-C matching network. The differential waveguide 171 prior to matching element 172 comprises the quarter-wavelength transformer. The parasitic capacitor comprises the sandwich consisting of the top spiral 174, thin insulator and bottom metal plate which make up the MIM structure. It is appreciated that other impedance matching topologies and techniques can also be applied to the pixel circuit of the present invention.

Thermoelectric Balance

Regarding thermoelectric balance, to simplify the description, the pixel circuit effectively ignores the impedance matching network and assumes the antenna is perfectly matched to the load directly. If such matching does not exist, however, an appropriate loss factor should be taken into account. Alternatively, the impedance matching network can be considered as part of the antenna thus establishing a purely ohmic high impedance antenna source.

Antenna and Load Resistor Electrical Modeling

In one embodiment, the antenna can be represented as a power source with output resistance R_{eq} and power Pᵣ, where Pᵣ denotes the power received by the antenna. It can be shown that Pᵣ is directly proportional to the thermal radiation received by the antenna multiplied by one or more antenna parameters (e.g., effective area, efficiency and bandwidth).

As described supra, in one embodiment, the antenna is loaded by a small-signal load that comprises a resistor parallel to the rectifying element. In some embodiments, if the rectifying element is tuned appropriately, the load resistor becomes negligible and can be ignored. The small-signal load, having resistive properties, can be modeled as a Johnson noise source with the same resistance R_{eq} and temperature Tₐ, where Tₐ denotes the ambient sensor temperature. The Johnson noise power at high frequencies such as terahertz frequencies is given by Equation 1 below:

$${P}_{n} = 4 {\int }_{{f}_{start}}^{{f}_{stop}} \frac{hf}{\frac{hf}{{e}^{{K}_{B} {T}_{a}}} - 1} d f \qquad ( 1 )$$

where

Pₙ is the thermal noise power expressed in [W];

h≈6.6×10⁻³⁴ is Planck's constant expressed in [J*Sec];

K_{B}=1.38×10⁻²³ is Bolzman's constant expressed in [J/° K];

Tₐ is temperature expressed in [° K];

fₛₜₐᵣₜ, fₛₜₒₚ is the frequency band over which the power is integrated [Hz]

A schematic diagram illustrating the equivalent electrical circuit of the antenna and load resistor and small-signal model of the rectifier is shown in FIG. 13. The model circuit, generally referenced 180, is the equivalent electrical circuit representing the balance created between the antenna and the load resistor. For the sake of completion, two loads in parallel are presented, namely a resistor and a rectifying element. If the resistor can be considered negligible or is not needed it can be removed from the equivalent electrical circuit.

The equivalent electrical circuit 180 comprises an antenna equivalent circuit 181 and a load resistor equivalent circuit. The antenna equivalent circuit 181 comprises a voltage source 182 in series with resistor R_{eq} 184. The load resistor equivalent circuit 182 comprises the series combination of voltage source 188 and resistor R 186 in parallel with the series combination of voltage source 192 and resistor R_{D} 190.

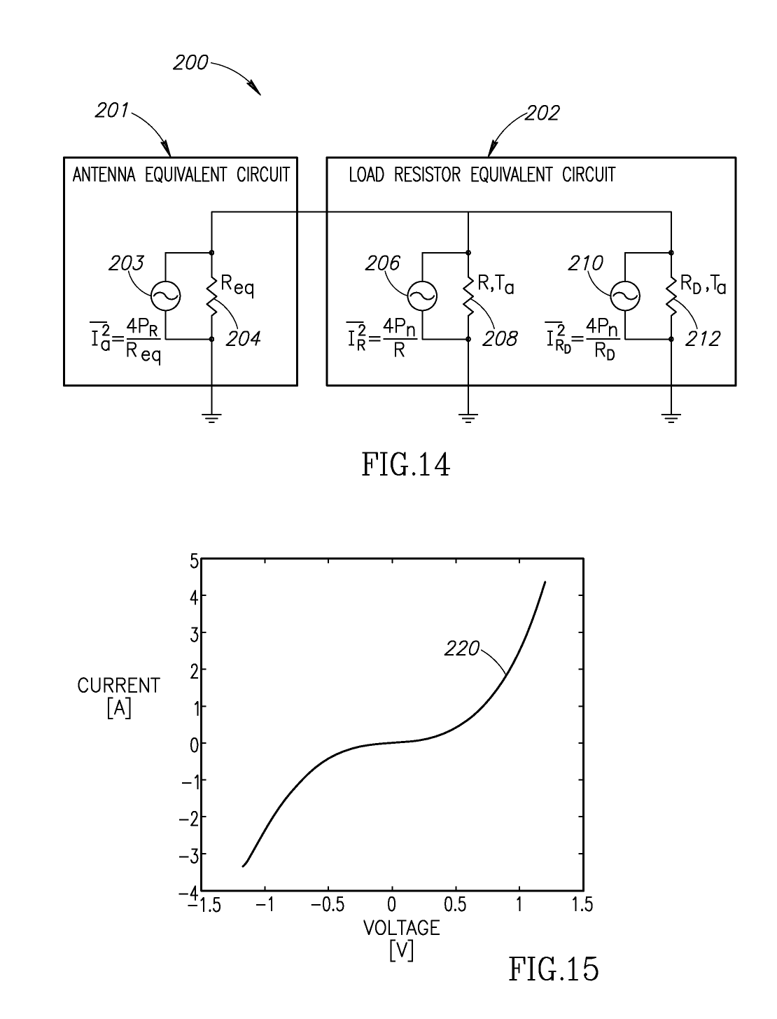

A schematic diagram illustrating the Norton equivalent electrical circuit of the antenna and load resistor and small-signal model of the rectifier is shown in FIG. 14. The circuit, generally referenced 200, is the same as circuit 180 of FIG. 13 wherein all the models have been converted into Norton equivalent circuits. In particular, the Norton equivalent electrical circuit 200 comprises an antenna equivalent circuit 201 and a load resistor parallel to a small-signal rectifier equivalent circuit 202. The antenna equivalent circuit 201 comprises current source 203 in parallel with resistor R_{eq} 204. The load resistor equivalent circuit 202 comprises the parallel combination of current source 206 and resistor R 208 in parallel with current source 210 and resistor R_{D} 212.

Where (for both circuits 180, 200 of FIGS. 13, 14, respectively):

R_{eq} denotes the equivalent antenna output impedance;
R is the load resistor;
R_{D} is the small signal resistance of rectifier D (FIG. 2 for example);
Iₐ is the antenna current source, representing the power absorbed by the antenna;
I_{R} is the load resistor current source, representing the thermal noise power generated by the resistor R;
I_{RD} is rectifier current source, representing the noise power generated by the rectifier D;

Analyzing the current divider yields the following expression (Equation 2).

$${I}_{D} = ( {I}_{a} + {I}_{R} + {I}_{{R}_{D}} ) * [ \frac{( {R}_{eq} \vert \vert R )}{( {R}_{eq} \vert \vert R ) + {R}_{D}} ] \qquad ( 2 )$$

The current I_{D} represents the small-signal current flowing through rectifier D.

### Rectification and Detection

The amplitude of the voltage V of the electrical signal output of the antenna is detected using a rectifying element. The electrical output signal is rectified and the DC bias obtained in measured. Note that any type of rectifier on the load resistor end would yield a DC bias that is proportional to the voltage across the load resistor. Depending on the particular implementation of the pixel circuit of the present invention, several techniques may be used to rectify a signal at frequencies in the terahertz range. For example, GaAs Schottky diodes and Metal-Insulator-Metal (MIM) tunnel junction devices are two technologies that are suitable for use at such high frequency bands.

GaAs Schottky diodes are based on Gallium Arsanide, which is a semiconductor with very high electron mobility. GaAs Schottky diodes have a higher saturated electron velocity and higher electron mobility (compared to silicon based diodes), allowing diodes from it to function at THz frequencies.

Metal-insulator-metal (MIM) structures essentially comprise two conducting layers separated by a thin insulator. The insulator is sufficiently thin to permit a tunnel current to flow when DC voltage is applied between the two conductors. Since the tunnel current is exponentially proportional to voltage, MIM structures can effectively function as small-signal rectifiers. A plot illustrating an example tunnel junction MIM I(V) curve is shown in FIG. 15. The curve 220 represents the I(V) curve of a typical MIM structure. Note the exponential response which is observed at approximately +/−1 volt.

Following the rectification stage, the rectified DC output signal is sensed. Note that the DC rectified signal can be voltage, current or both. Thus two types of signal sensing are applicable, namely series current sensing and parallel voltage sensing. Series current sensing is achieved by placing the rectifier in series with the antenna and sensing the output current. Current sensing is the type of sensing shown in FIGS. 3, 4, 7 and 8. Parallel voltage sensing is achieved by placing the rectifier in parallel with the antenna and sensing the voltage developed across it. Voltage sensing is the type of sensing shown in FIGS. 5, 6, 9, and 10.

In an example embodiment, a capacitor C is placed at the output of the rectifier, such as in FIGS. 3, 4, 7 and 8. Capacitor C is charged to a DC voltage through the rectifier D. The charge current can be derived from Equation 2 and is presented in Equation 3 below:

$$\begin{matrix}{I}_{c} = {I}_{{D}^{+}} - {I}_{{D}^{-}} \\ = ( {I}_{a} + {I}_{R} + {I}_{{R}_{D}^{+}} ) * [ \frac{( {R}_{eq} \vert \vert R )}{( {R}_{eq} \vert \vert R ) + {R}_{D}^{+}} ] - ( {I}_{a} + {I}_{R} + {I}_{{R}_{D}^{-}} ) * \\ [ \frac{( {R}_{eq} \vert \vert R )}{( {R}_{eq} \vert \vert R ) + {R}_{D}^{-}} ]\end{matrix} \qquad ( 3 )$$

where
I_{C} is the rectified current charging capacitor C;
I_{D}_{⁺},I_{D}_{^{−}} is the current flowing through the rectifier in the positive and negative polarities of the small signal, respectively;
I_{R}_{⁺}_{_{D}},I_{R}_{^{−}}_{_{D}} is rectifier current source, representing the thermal noise power generated by the rectifier in the positive and negative polarities of the small signal, respectively;
R_{D}⁺,R_{D}⁻ is small signal rectifier resistance in the positive and negative polarities of the small signal, respectively;

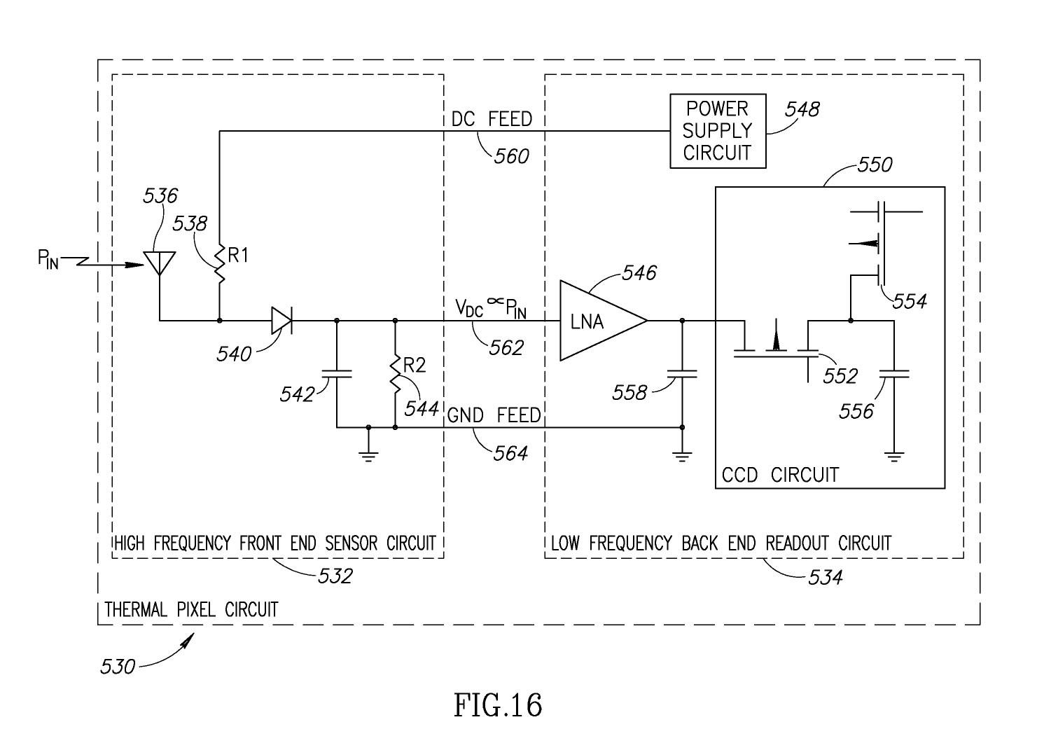

The DC voltage across the capacitor C is proportional to the AC voltage induced on the load resistor R (e.g., resistor 544, FIG. 16). Note that a discharging element is preferably placed in parallel to capacitor C to keep the capacitor from saturating. The discharging element may comprise a resistor, a trans-impedance amplifier or any other type of discharging circuit. The discharging element enables dynamic tracking of the received signal strength.

DC Biasing

In some example embodiments, the rectifying element requires DC biasing for operation. This may be due to several reasons, such as (1) the rectifier is not sufficiently non-linear around zero bias, thus rectification is not achieved without biasing; (2) the small signal resistance reflected by the rectifier is too high around zero bias, thus significant signal sensing is not achieved due to impedance mismatch between the antenna and the load. Note that in other cases, biasing is not needed and the system can be completely passive. The circuits of FIGS. 4, 6, 8 and 10 illustrate unbiased topologies of the pixel circuit. The circuits of FIGS. 3, 5, 7, and 9 illustrate biased topologies of the pixel circuit.

Isolated Front End Sensor and Backend Readout Circuits

A schematic diagram illustrating an example monolithic CMOS implementation of the thermal pixel front and back end circuits is shown in FIG. 16. The thermal pixel circuit, generally referenced 530, comprises two portions: (1) a high frequency front end circuit 532 and a low frequency back-end circuit 534. The interface between the two circuits comprises a DC feed 560, V_{AC} signal output 562 which is proportional to P_{IN} and a ground feed 564. The front end circuit 532 comprises antenna 536, resistor R1 538, rectifying element 540, capacitor 542 and resistor 544. The backend circuit 534 comprises amplifier (e.g., LNA) 546, capacitor 558 and CCD circuit 550 which comprises a plurality of switches 552, 554 and capacitor 556.

The front end circuit comprises the high frequency portion which receives the terahertz black body radiation. The antenna 536 is adapted to receive black body radiation in the desired frequency range, e.g., SWIR, MWIR, LWIR, etc., and converts the electromagnetic radiation to an electrical signal, thus functioning as a transducer. The electrical signal is rectified by rectifying element 540 which comprises, in an example embodiment, a MIM tunnel junction device. The rectified electrical signal, which is now a DC voltage, is fed to the backend readout circuit where it is amplified (via LNA 546) and read out for display to a user or further processing. For example, the pixel information is read out via the CCD circuit 550 (or any other type of suitable read out circuit) for updating a user display at video frame rates.

In the example embodiment presented herein the pixel is 25×25 μm in size. Other sizes can also be used depending on the particular implementation. The antenna area makes up the majority of the physical size of the pixel circuit. Thus, pixel size is typically determined mostly by antenna area. The bigger the antenna, the better the gain and the higher the sensitivity achieved. Note that a bigger antenna does not necessarily translate to a lower resolution since resolution is largely determined by the number of pixels. The number of pixels combined with the optical channel (i.e. lens) features determines the field of view. Pixel size may be as small as ½λ which is approximately 5×5 μm (assuming 30 THz radiation) which is close to the minimum antenna size that can still effectively sense the radiation. Note that the two circuits, i.e. the front end and back end circuits, are isolated from each other wherein the only interface between them are the DC feed 560, V_{AC} signal output 562 and ground feed 564.

1D, 2D and Stereoscopic Pixel Arrays

In an alternative embodiment, the single pixel circuit (such as circuit 530, FIG. 16) is duplicated and used to construct arrays of pixels. For example, a plurality of pixel circuits can be used to construct a one-dimensional array, two-dimensional array and a stereoscopic array. These are described in more detail infra.

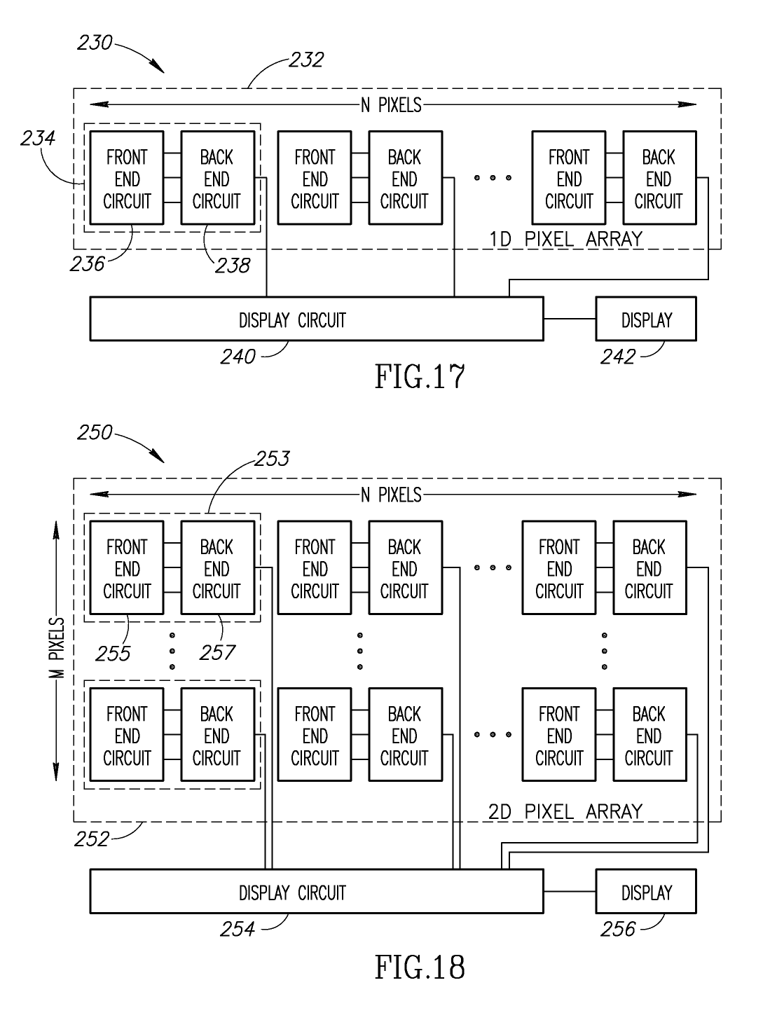

A diagram illustrating an example one dimensional thermal pixel array is shown in FIG. 17, such as can be used to scan a thermal image. The 1D pixel array, generally referenced 230, comprises a plurality of pixel circuits 232 arranged in a linear array N wide, display circuitry 240 and display 242. The array of pixel circuits comprises a plurality of single pixel circuits 234 constructed on a single monolithic die of silicon wherein each pixel circuit comprises a high frequency front end circuit 236 and a low frequency back end read out circuit 238. The pixel information is read out of the back end circuit and processed by the display circuit 240 for presentation to a user on display 242. An optical system of one or more lenses (not shown) may be placed before the array to channel and focus the black body radiation onto the array.

A diagram illustrating an example two dimensional thermal pixel array is shown in FIG. 18. The 2D pixel array, generally referenced 250, comprises a plurality of pixel circuits 252 arranged in a 2D array of size N×M (e.g., 320×240), display circuitry 254 and display 256. The 2D array of pixel circuits comprises a plurality of single pixel circuits 253 constructed on a single monolithic die of silicon wherein each pixel circuit comprises a high frequency front end circuit 255 and a low frequency back end read out circuit 257. The pixel information is read out of the back end circuit and processed by the display circuit 254 for presentation to a user on display 256. An optical system of one or more lenses (not shown) may be placed before the array to channel and focus the black body radiation onto the array.

A stereoscopic array (not shown) is also contemplated by the present invention. The stereoscopic array comprises a pair of 2D pixel arrays (2D pixel array 250, FIG. 18) placed a distance apart from each other to achieve stereo imaging. Note that both 2D arrays may be constructed on a single monolithic die of silicon or each 2D array may be constructed on separate silicon dies. An optical system of one or more lenses (not shown) may be placed before each 2D pixel array to channel and focus the black body radiation onto each respective 2D pixel array.

Note in the 1D, 2D or stereoscopic array embodiments, the back end circuit of each pixel comprises one or more switching transistors arranged to implement a Charge Coupled Device (CCD) readout mechanism. The CCD readout mechanism associated with each pixel functions to read out the sensed signals from the entire pixel array. It should be noted that other readout mechanisms are also applicable for use with the present invention, depending on the particular implementation.

It is noted that in the 1D, 2D or stereoscopic array embodiments, the resolution is dictated by the pixel size. Pixel size is mostly determined by the size of the antenna which takes up most of the silicon real estate when implemented. The size of the array is typically dictated by the required resolution. Once the required resolution is known, the array size can be determined based on it.

### Example Unbalanced Pixel Circuits

Several example pixel circuits are presented infra to aid in illustrating the possible variations of the pixel circuit of the present invention. Four example pixel circuits are shown illustrating unbalanced, biased and unbiased, and voltage and current sense topologies. It is appreciated that the present invention is not limited to the example pixel circuits presented herein as one skilled in the electrical art can construct other circuit topologies in accordance with the principles of the invention.

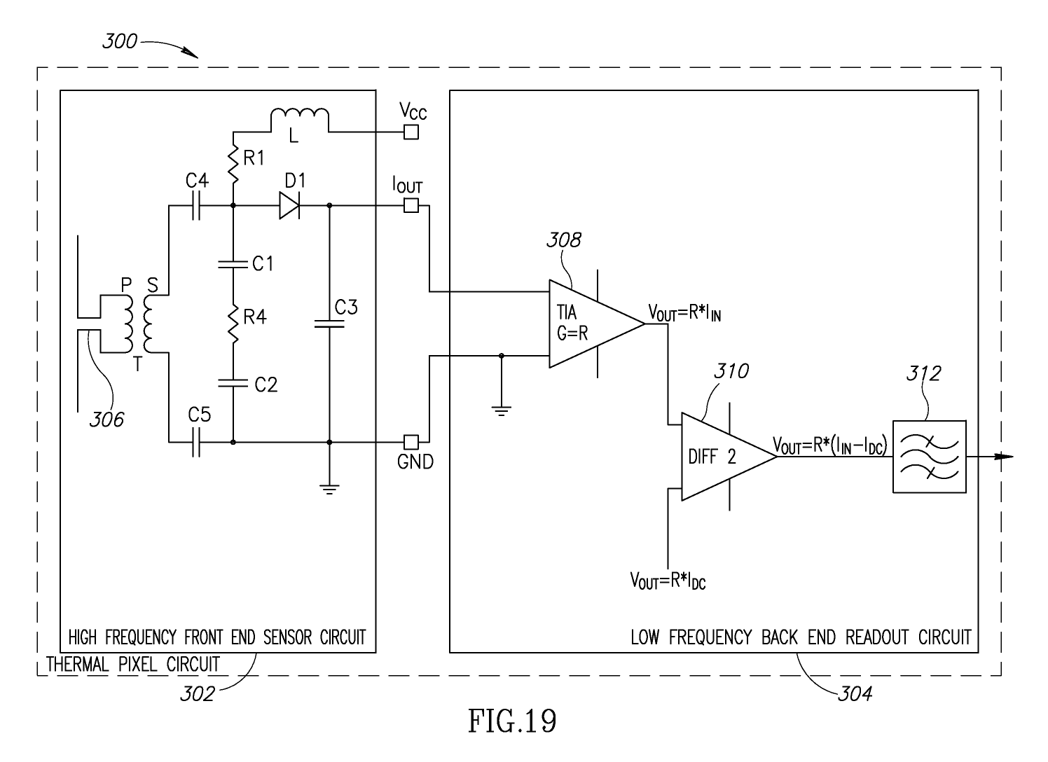

A schematic diagram illustrating an example balanced, biased topology, current sense pixel circuit is shown in FIG. 19. The thermal pixel circuit, generally referenced 300, comprises a high frequency front end sensor circuit portion 302 and a low frequency back end readout circuit portion 304. The front end circuit sensor circuit comprises an antenna 306, transformer T/impedance matching network, series capacitor C₄ tied to series combination of capacitor C₁, resistor R₄ and capacitor C₂, rectifier D₁ whose DC output voltage charges capacitor C₃ connected to ground, and biasing circuit resistor R₁ and inductor L tied to V_{CC}.

The backend readout circuit comprises current sense trans-impedance amplifier 307 whose inputs include the rectified output voltage developed across C₃ and ground. The output of the trans-impedance amplifier is input to a differential amplifier 310 whose output is filtered via lowpass filter 312 before being read out to the display circuitry. Note that in an example embodiment, both the front end and back end circuits are constructed on a monolithic silicon substrate using standard integrated circuit fabrication techniques.

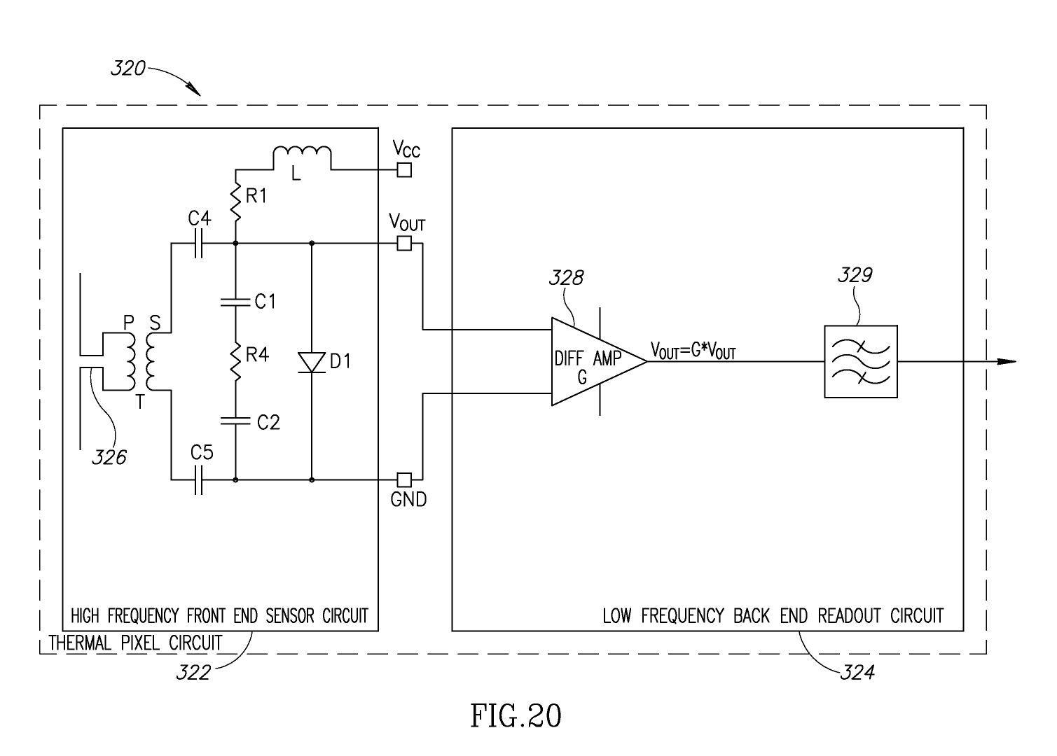

A schematic diagram illustrating an example unbalanced, biased topology, voltage sense pixel circuit is shown in FIG. 20. The thermal pixel circuit, generally referenced 320, comprises a high frequency front end sensor circuit portion 322 and a low frequency back end readout circuit portion 324. The front end circuit sensor circuit comprises an antenna 326, transformer T/impedance matching network, series capacitor C₄ tied to series combination of capacitor C₁, resistor R₄ and capacitor C₂, in parallel with rectifier D₁, and biasing circuit resistor R₁ and inductor L tied to V_{CC}. The DC voltage developed across the rectifier is input to the backend circuit.

The backend readout circuit comprises differential amplifier 328 whose inputs include the rectified output voltage across rectifier D₁ and ground. The output of the amplifier is filtered via lowpass filter 329 before being read out to the display circuitry. Note that in an example embodiment, both the front end and back end circuits are constructed on a monolithic silicon substrate using standard integrated circuit fabrication techniques.

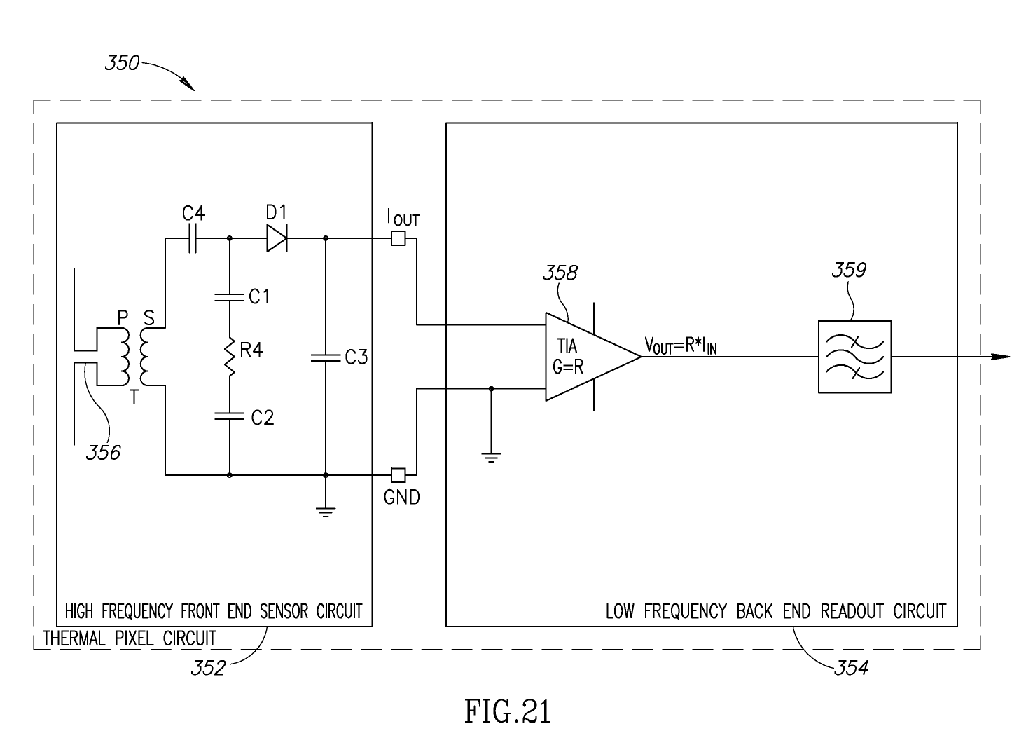

A schematic diagram illustrating an example unbalanced, unbiased topology, current sense pixel circuit is shown in FIG. 21. The thermal pixel circuit, generally referenced 350, comprises a high frequency front end sensor circuit portion 352 and a low frequency back end readout circuit portion 354. The front end circuit sensor circuit comprises an antenna 356, transformer T/impedance matching network, series capacitor C₄ tied to series combination of capacitor C₁, resistor R₄ and capacitor C₂ and rectifier D₁ whose DC output voltage charges capacitor C₃ connected to ground.

The backend readout circuit comprises current sense trans-impedance amplifier 358 whose inputs include the rectified output voltage developed across C₃ and ground. The output of the trans-impedance amplifier is filtered via lowpass filter 359 before being read out to the display circuitry. Note that in an example embodiment, both the front end and back end circuits are constructed on a monolithic silicon substrate using standard integrated circuit fabrication techniques.

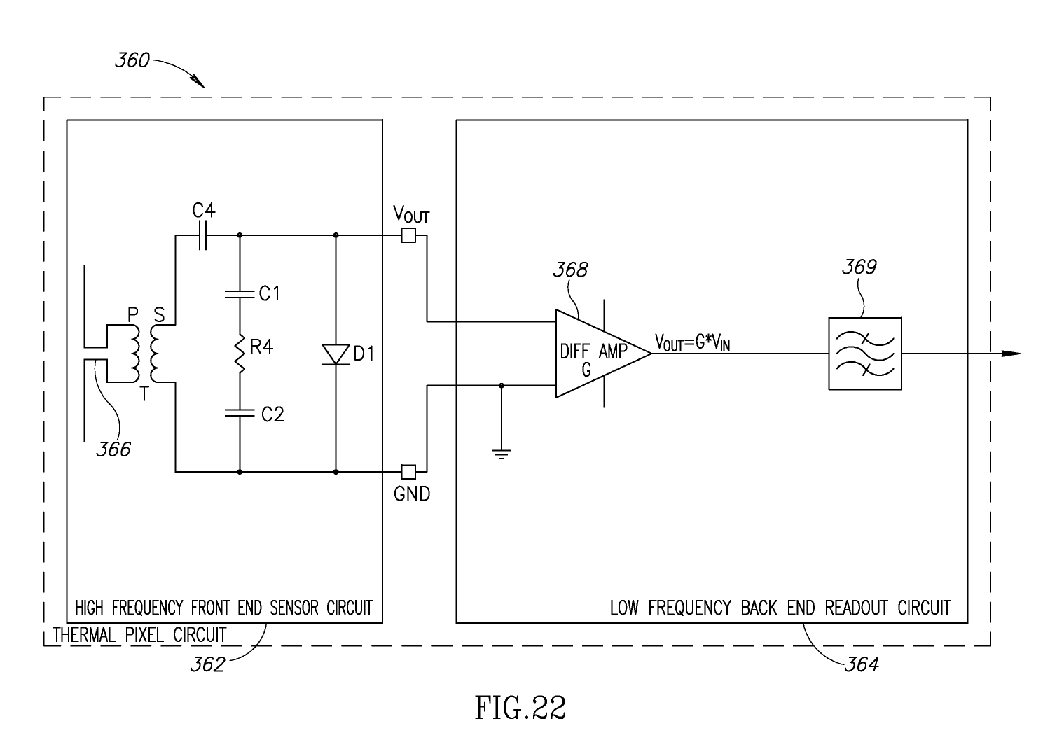

A schematic diagram illustrating an example unbalanced, unbiased topology, voltage sense pixel circuit is shown in FIG. 22. The thermal pixel circuit, generally referenced 360, comprises a high frequency front end sensor circuit portion 362 and a low frequency back end readout circuit portion 364. The front end circuit sensor circuit comprises an antenna 366, transformer T/impedance matching network, series capacitor C₄ tied to series combination of capacitor C₁, resistor R₄ and capacitor C₂ in parallel with rectifier D₁. The DC voltage developed across the rectifier is input to the backend circuit.

The backend readout circuit comprises differential amplifier 368 whose inputs include the rectified output voltage across rectifier D₁ and ground. The output of the amplifier is filtered via lowpass filter 369 before being read out to the display circuitry. Note that in an example embodiment, both the front end and back end circuits are constructed on a monolithic silicon substrate using standard integrated circuit fabrication techniques.

Differential Sensor and Readout Circuits

When implementing the pixel circuit of the present invention, the high frequency front end circuit portion is isolated from the low frequency back end circuit portion. If the two circuits are not sufficiently isolated, system performance may degrade significantly due to crosstalk, signal leakage and cross loadings of the two circuits.

It is further noted that the challenge of isolating the high frequency front end sensor circuit (e.g., SWIR, MWIR, LWIR other) from the low frequency back end readout circuit becomes even more significant considering the integrated circuit process technologies used to construct both single pixels and pixel arrays. The thermal pixel of the present invention provides a mechanism to maximize isolation between the system front end sensor circuit and the back end readout circuit. The mechanism comprises providing fully differential high frequency front end sensor circuit which effectively provides “natural” isolation between the front end and the back end portions of the pixel circuit. In one embodiment, the only interface between the two circuit portions are power signals (DC and ground) and the rectified output signal in differential form. A perfectly balanced interface (i.e. fully differential) yields a perfect common mode rejection ratio (CMRR) thus significantly improving system performance.

Several example pixel circuits are presented infra to aid in illustrating the possible variations of the pixel circuit of the present invention. Four example pixel circuits are shown illustrating balanced, biased and unbiased, and voltage and current sense topologies. It is appreciated that the present invention is not limited to the example pixel circuits presented herein as one skilled in the electrical art can construct other circuit topologies in accordance with the principles of the invention.

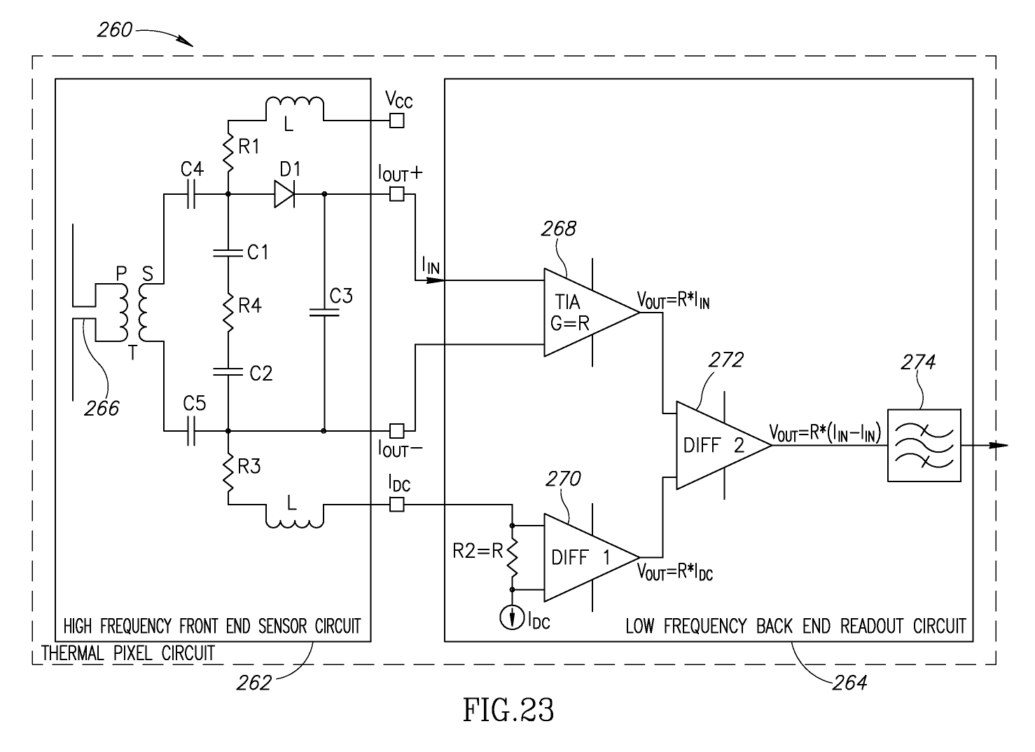

A schematic diagram illustrating an example differential, biased topology, current sense pixel circuit is show in FIG. 23. The thermal pixel circuit, generally referenced 260, comprises a high frequency front end sensor circuit portion 262 and a low frequency back end readout circuit portion 264. The front end circuit sensor circuit comprises an antenna 266, transformer T/differential impedance matching network tied to series capacitors C₄ and C₅ connected across a series combination of capacitor C₁, resistor R₄ and capacitor C₂, rectifier D₁ whose DC output voltage charges capacitor C₃, a biasing circuit coupled to capacitor C₄ comprising resistor R₁ and inductor L tied to V_{CC}, and a biasing circuit coupled to capacitor C₅ comprising resistor R₃ and inductor L tied to current source I_{DC}.

The backend readout circuit comprises current sense trans-impedance amplifier 268 whose differential inputs include the differential current I_{OUT+} and I_{OUT-} developed across C₃. Current from current source I_{DC} generated a voltage across resistor R₂ which is input to differential amplifier 270 and provides biasing for the front end circuit. The inputs to differential amplifier 272 comprise the outputs of trans-impedance amplifier 268 and differential amplifier 270. The output of differential amplifier 272 is filtered via lowpass filter 274 before being read out to the display circuitry. Note that in an example embodiment, both the front end and back end circuits are constructed on a monolithic silicon substrate using standard integrated circuit fabrication techniques.

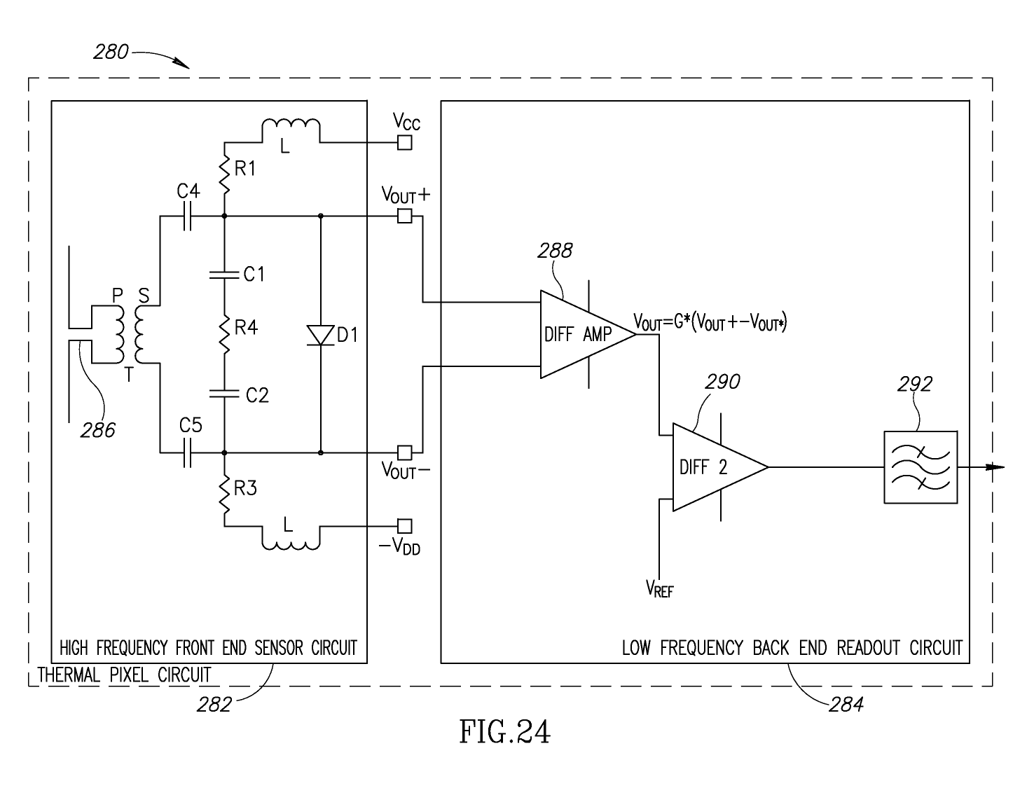

A schematic diagram illustrating an example differential, biased topology, voltage sense pixel circuit is shown in FIG. 24. The thermal pixel circuit, generally referenced 280, comprises a high frequency front end sensor circuit portion 282 and a low frequency back end readout circuit portion 284. The front end circuit sensor circuit comprises an antenna 286, transformer T/impedance matching network, series capacitors C₄ and C₅ connected across series combination of capacitor C₁, resistor R₄ and capacitor C₂, in parallel with rectifier D₁, a biasing circuit coupled to capacitor C₄ comprising resistor R₁ and inductor L tied to V_{CC}, and a biasing circuit coupled to capacitor C₅ comprising resistor R₃ and inductor L tied to −V_{DD}. The DC voltage developed across the rectifier is input to the backend circuit.

The backend readout circuit comprises differential amplifier 288 whose inputs include the rectified differential output voltage V_{OUT+} and V_{OUT-} developed across rectifier D₁. The output of the differential amplifier 288 is input to another differential amplifier 290 whose second input comprises a reference voltage V_{REF}. The output of the differential amplifier 290 is filtered via lowpass filter 292 before being read out to the display circuitry. Note that in an example embodiment, both the front end and back end circuits are constructed on a monolithic silicon substrate using standard integrated circuit fabrication techniques.

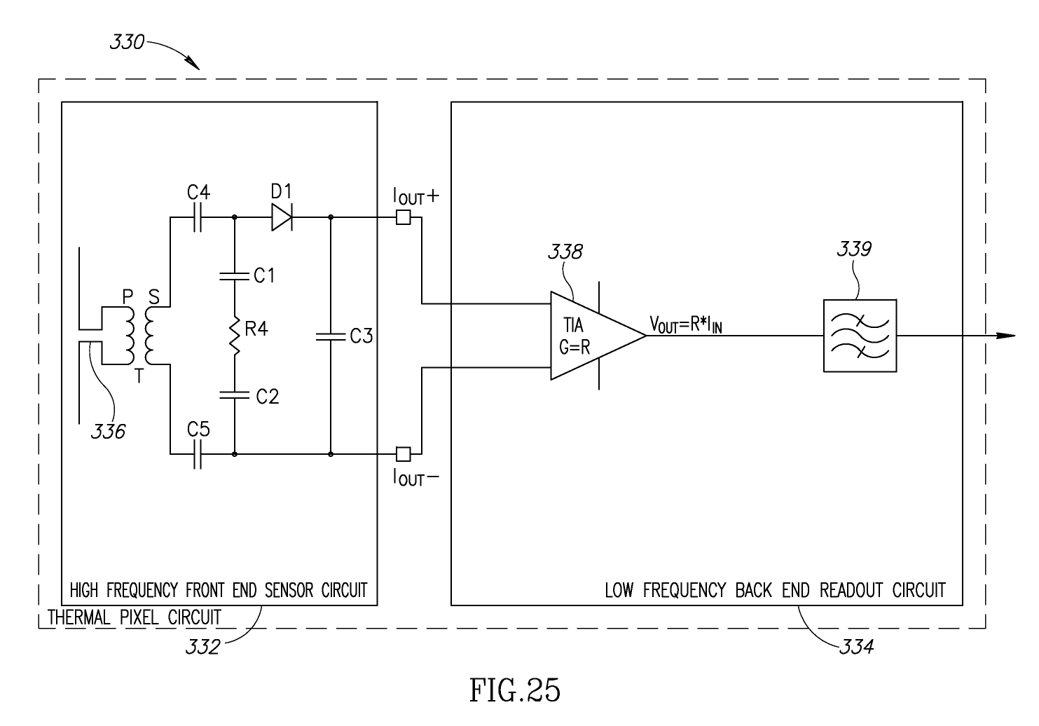

A schematic diagram illustrating an example differential, unbiased topology, current sense pixel circuit is shown in FIG. 25. The thermal pixel circuit, generally referenced 330, comprises a high frequency front end sensor circuit portion 332 and a low frequency back end readout circuit portion 334. The front end circuit sensor circuit comprises an antenna 336, transformer T/differential impedance matching network tied to series capacitors C₄ and C₅ connected across a series combination of capacitor C₁, resistor R₄ and capacitor C₂, rectifier D₁ whose DC output voltage charges capacitor C₃, a biasing circuit coupled to capacitor C₄ comprising resistor R₁ and inductor L tied to V_{CC}, and a biasing circuit coupled to capacitor C₅ comprising resistor R₃ and inductor L tied to current source I_{DC}.

The backend readout circuit comprises current sense trans-impedance amplifier 338 whose differential inputs include the differential current I_{OUT+} and I_{OUT-} developed across C₃. The output of the trans-impedance amplifier 338 is filtered via lowpass filter 339 before being read out to the display circuitry. Note that in an example embodiment, both the front end and back end circuits are constructed on a monolithic silicon substrate using standard integrated circuit fabrication techniques.

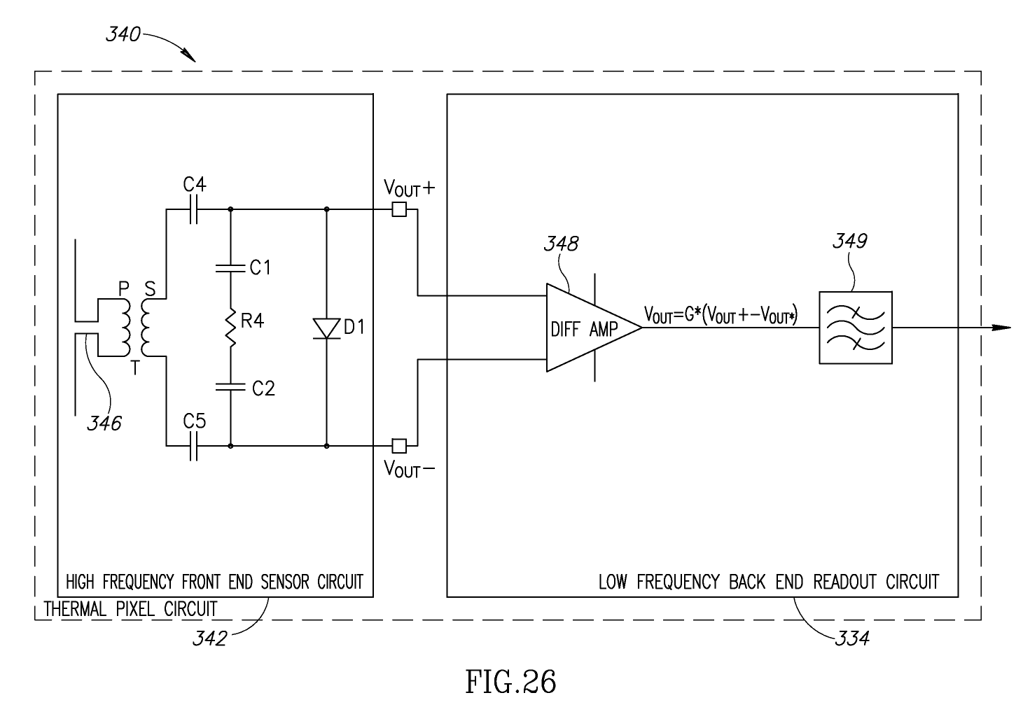

A schematic diagram illustrating an example differential, unbiased topology, voltage sense pixel circuit is shown in FIG. 26. The thermal pixel circuit, generally referenced 340, comprises a high frequency front end sensor circuit portion 342 and a low frequency back end readout circuit portion 344. The front end circuit sensor circuit comprises an antenna 346, transformer T/impedance matching network, series capacitors C₄ and C₅ connected across series combination of capacitor C₁, resistor R₄ and capacitor C₂, in parallel with rectifier D₁. The DC voltage developed across the rectifier is input to the backend circuit.

The backend readout circuit comprises differential amplifier 288 whose inputs include the rectified differential output voltage V_{OUT+} and V_{OUT-} developed across rectifier D₁. The output of the differential amplifier 348 is filtered via lowpass filter 349 before being read out to the display circuitry. Note that in an example embodiment, both the front end and back end circuits are constructed on a monolithic silicon substrate using standard integrated circuit fabrication techniques.

Antenna and Impedance Matching

In one differential example embodiment of the invention, the antenna comprises a differential interface. Note that there are numerous types of antenna topologies having a differential interface. Examples include, but are not limited to single units, complete antenna arrays, dipole antennas, loop antennas, etc. The Vivaldi antenna 160 shown in FIG. 11 is another example of an antenna having a differential interface. Since the antenna is differential, it does not comprise a ground plane. The antenna interface is a symmetrical structure with two identical opposite ends operating one against the other. Positioning a reflective plane behind the antenna, however, can enhance not only the gain of the antenna but its directivity and efficiency as well. In an example embodiment, the reflective plane may comprise, a metallic film positioned a quarter of a wavelength from the antenna. Note that the reflective plane is not required to be electrically connected to the antenna. The reflective plane functions as an equi-potential plane that reflects the electromagnetic field that meets it.

The output of the antenna is input to a differential impedance matching network (for example blocks 104, 124, 134, 154 in FIGS. 7, 8, 9, 10, respectively). The differential impedance matching network can be based on lumped elements, distributed elements or a combination of both lumped and distributed elements. The matching network may comprise, for example, differential transmission lines (e.g., differential micro strip), transformer structures and other elements as required by the particular circuit implementation.

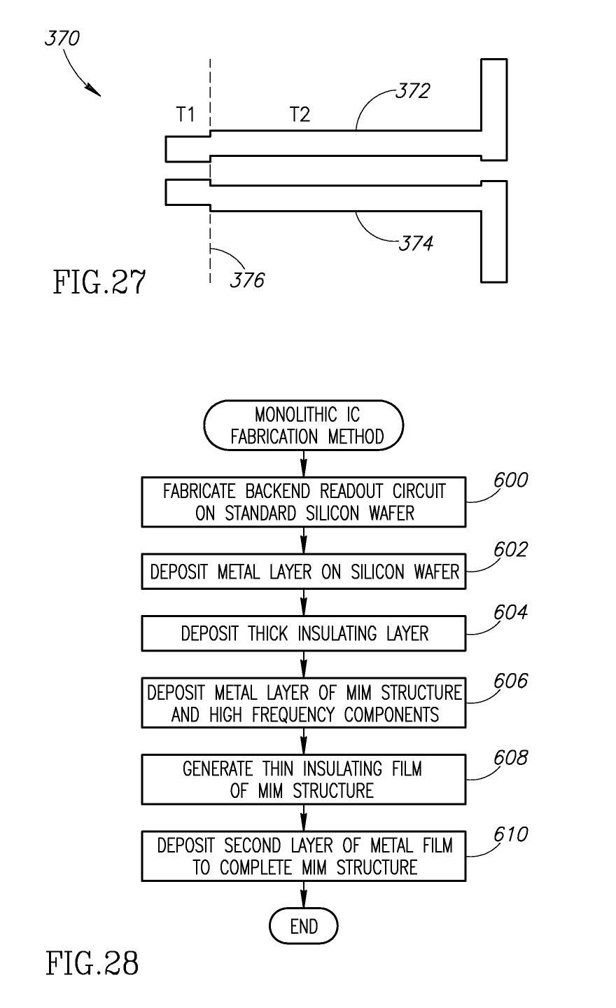

A diagram illustrating an example differential quarter wavelength co-planar transformer is shown in FIG. 27. The transformer, generally referenced 370, comprises two symmetrical elements 372, 374 which together form two transformers T1 and T2 separated at dashed line 376. Normally, the antenna is connected to the open end (left) of T1 and the rectifying element (e.g., MIM) is connected to the open end (right) of T2.

Antenna Load

The antenna (followed by the impedance matching network) is loaded by two elements in parallel, namely (1) a load resistor R(R₄ in FIGS. 19 to 26, for example) connected across the differential impedance matching network interface; and (2) a rectifying element D (D₁ in FIGS. 19 to 26, for example) connected either in a series or parallel configuration. Note that although some schematic drawings are not completely symmetrical, the rectifying element D is also part of the differential structure. The equivalent load is denoted as R_{eq}=R∥R_{D}.

Interface to Low Frequency Backend Readout Circuit

A DC interface is provided between the front end sensor and backend readout circuits. The DC interface functions to feed power and ground to the terahertz front end sensor circuit. The interface is based on two points, including (1) a power source V_{CC}; and (2) a current source I_{DC}. Note that the current source functions to forward bias the rectifier D. Both the power and current source interfaces are fed through inductors L. The inductors present an impedance defined as Z_{L}=j2πfL. Preferably, inductance L is set large enough to reflect very high impedance in the high frequency band (e.g., SWIR, MWIR or LWIR region). Thus, inductors L function as isolating elements separating the high frequency signals from low frequency signals.

Detected Signal

Referring to the pixel circuits of FIGS. 23, 24, 25, 26, the detected signal Iₒᵤₜ is fed into a trans-impedance amplifier (268, 288, 308, 328 in FIGS. 23, 24, 25, 26, respectively. The trans-impedance amplifier converts the detected signal Iₒᵤₜ into voltage. In accordance with well-known circuit theory, the same current flowing into the trans-impedance amplifier (Iₒᵤₜ⁺) also flows out of the trans-impedance amplifier (Iₒᵤₜ⁻). Under such a topology, the current flows in a closed-loop manner from the front end circuit to the backend circuit and back into the front end circuit. Using a differential topology functions to minimize the common mode noise between the high frequency front end sensor circuit and the low-frequency back end readout circuit. It is appreciated by one skilled in the art that other readout circuit topologies are also applicable. For example, a resistor (not shown) may be added to discharge the capacitor C, followed by a differential amplifier that also functions as part of a differential signal readout circuit.

Several advantages of the differential pixel circuits described supra include the elimination of parasitic and radiation losses. Consider that the pixel circuit is operative to detect electromagnetic signals in the IR frequency bands, e.g., SWIR, MWIR, LWIR. Signals in the frequency range (e.g., in the LWIR band) having a typical frequency of 30 THz and typical wavelength of 10 μm are typically difficult to manage and isolate from the environment. The high terahertz frequency causes every parasitic capacitance to act as a potential short or at the least a low impedance load. Further, the short wavelength of terahertz energy requires a distributed design of the pixel circuit. A distributed design, however, is more susceptible to the environment, as distributed elements tend to radiate and reflect, radiate and cause unintended losses and couplings. The losses and couplings can be avoided and the radiation canceled out by using the differential pixel circuit topologies of the present invention. The differential circuit mechanisms presented herein functions to minimize and even eliminate the radiation and ensuing losses. The differential pixel circuit topology is operative to cancel itself out to the outside world, thereby helping to maintain all the IR energy and signal within the intended path.

Another advantage of the differential pixel circuits is the elimination of practical losses due to ground planes. The differential techniques presented herein eliminate the need for any type of ground plane or signal. It is virtually impossible to construct a perfect ground plane at terahertz frequencies due to the following two reasons (1) the skin effect of the electrical conductors become significant at such high frequencies which acts to enhance the resistive nature of metals; and (2) the well known Drude model (which considers metal to be formed of a mass of positively charged ions from which a number of free electrons are detached) enhances metal resistance but also the dispersive properties of metals. Thus, by using a differential mechanism the need of taking into account the practical losses associated with metal properties in IR bands (e.g., SWIR, MWIR, LWIR) is eliminated.

Monolithic Integrated Circuit Implementation

The single pixel circuit topology described supra can be adapted to be implemented on a single monolithic integrated circuit, such as on a silicon die. In one embodiment, the pixel circuit is implemented in a stacked structure configuration whereby the back-end amplifier and readout portion of the pixel circuit is implemented using standard integrated circuit processing techniques (e.g., silicon components) while the front-end THz receiver (e.g., 30 THz receiver) is fabricated using metal and insulating layers deposited over the back-end readout circuit. Thus, standard integrated circuit technology is used to fabricate such a monolithic pixel for both the low frequency backend readout circuit which is fabricated first followed by the high frequency front end circuit fabricated second on top of the back end circuit. Examples of conventional, off-the-shelf integrated technologies suitable for use with the present invention include, but are not limited to, CMOS, BiPolar, Bi-CMOS, SiGe Bi-CMOS and GaAs. Note that it is appreciated that other processes are also applicable. Note that standard IC processing techniques are used to construct both the front end and back end circuits on a single monolithic die of silicon.

As described supra, prior art uncooled thermal imaging systems are very expensive to manufacture. Typically, the production process involves MEMS technology and very advanced vacuum packaging technologies, both of which are costly. Furthermore, both technologies are used uniquely in the uncooled thermal imager and cannot be shared with other market segments to leverage the economy of scale.

The thermal pixel of the present invention provides an alternative to uncooled thermal imaging which does not require the use of MEMS and vacuum packaging technology. Pixel circuits designed in accordance with the invention can be implemented using standard IC fabrication processes currently used in semiconductor foundries around the world. A high level description of the standard semiconductor processes used in fabricating the thermal imaging system of the invention is provided infra.

As described supra, the thermal imaging system (i.e. the pixel circuit) is divided into a high frequency front end sensor circuit and a low frequency backend readout circuit. The high frequency (e.g., 30 THz in one embodiment) front end comprises the sensor components from the antenna to the rectifying element. It is the LWIR (or SWIR, MWIR) band portion of the system operating in approximately, in one example embodiment, the 30 THz frequency range. The low frequency backend readout circuit functions to receive the output signal from the front end sensor circuit and enhance, filter and process (manipulate) the signal detected by the front end to optimize signal to noise ratio (SNR) and prepare the signal for downstream processing (e.g., to enable an imaging display at video frame rates, for example).

In one embodiment, the high frequency front end sensor circuit is implemented using thin film technologies. The front end segment (e.g., 30 THz) is realized by fabricating the antenna and other conducting elements of the sensor using thin film metals while the rectifying element is constructed using MIM techniques with thin film isolation. The low frequency backend readout circuit can be realized in numerous IC technologies. For example, it can be realized in CMOS, BiPolar, BiCMOS and many other standard semiconductor processes.

Example implementations of the pixel circuit for balanced and unbalanced topologies are described infra. The invention is not limited to these examples as one skilled in the art can construct numerous other implementations using the principles of the invention.

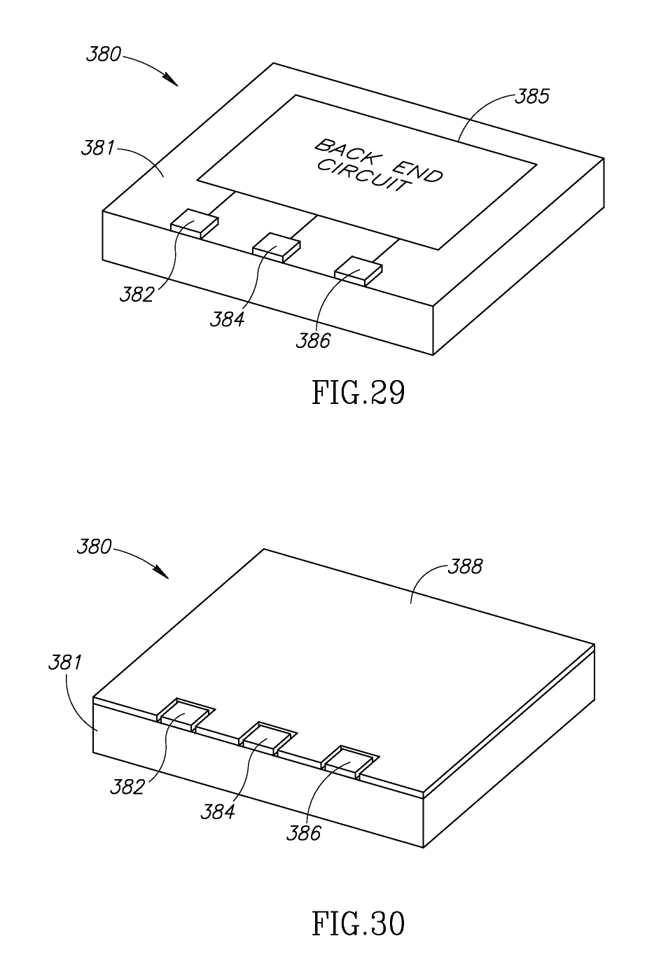

A flow diagram illustrating an example monolithic integrated circuit fabrication method is shown in FIG. 28. This method is applicable for both unbalanced and balanced versions of the pixel circuit. As an example, fabrication of an unbalanced pixel circuit is described first following by a balanced pixel circuit. A diagram illustrating a silicon IC wafer with the backend readout circuit implemented on it is shown in FIG. 29. With reference to FIGS. 28 and 29, as a first step, the entire backend readout circuit 385 is fabricated on a standard monolithic silicon substrate (wafer) 381 (step 600). At this stage, the pixel circuit, generally referenced 380, comprises a monolithic silicon substrate 381 upon which the backend readout circuit 385 is fabricated using standard IC functions and techniques. The IC wafer can be manufactured using any of the various available processes such as CMOS, BiCMOS, BiPolar, SiGe and others. Each die comprises several functions and blocks as required for the thermal detector to operate. The functions and blocks may comprise, for example, a differential amplifier, trans-impedance amplifier, analog switch for CCD implementation, DC current source, DC voltage source, analog to digital converter (ADC) and other functions depending on the particular implementation. The silicon die also comprises pads 382, 384, 386 to interface the silicon wafer containing the low frequency back end to the metal layers (not yet deposited) containing the high frequency front end. In this unbalanced pixel circuit example, pads 382, 384, 386 are provided for signal, V_{CC} and ground respectively.

A diagram illustrating the fabrication step of deposition of a thin metal layer on the IC wafer is shown in FIG. 30. With reference to FIGS. 28 and 30, as a next step, a metal layer 388 is deposited on the silicon wafer (step 602). Note that the metal layer is a conducting layer and is adapted to function as an IR reflector (e.g., SWIR, MWIR, LWIR) as described in more detail infra, thus it is preferable that the metal exhibit good conductivity in the IR bands. Example of such metals include gold, silver, copper and aluminum.

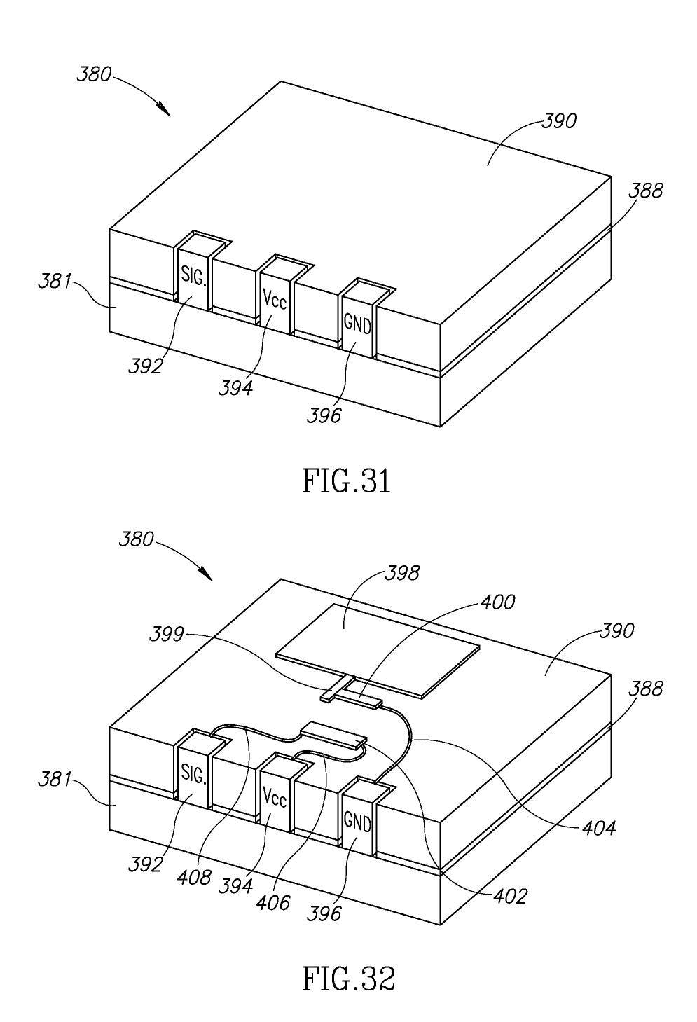

A diagram illustrating the fabrication step of deposition of a thick insulating layer on top of the metal layer is shown in FIG. 31. With reference to FIGS. 28 and 31, in a next step, a relatively thick insulating layer 390 is deposited over the metal layer 388 and the pads 392, 394, 396 for the signal, V_{CC}, ground, respectively, are lengthened (step 604). In one embodiment, the insulating layer 390 comprises a thick (e.g., approximately 2 μm) insulating layer on top of the metal layer 388 to allow electromagnetic waves of 10 μm wavelength to resonate in the insulating layer. In one embodiment, the insulator 390 comprises silicon dioxide (SiO₂). Alternatively, it comprises any type of insulator that is applicable to the particular IC process, such as aluminum oxide (Al₂O₃), palladium oxide or other insulating materials. The thickness of the insulator is configured such that it presents approximately a ¼ wavelength (in the LWIR band). The insulator layer 390, together with the reflective metal layer 388 below it, function to enhance the gain of the antenna deposited over it. Therefore, configuring the insulator thickness to be approximately ¼ wavelength optimizes the reflective effect. Note that the insulating layer may have thicknesses other than ¼ wavelength depending on the purpose the insulator is to serve. It is noted that preferably the thickness of the insulator is calculated taking into account the refractive index of the insulator material in the band of interest, e.g., SWIR, MWIR, LWIR, etc. For example, assuming the insulator refractive index is greater than one, its thickness will most likely be less than 2.5 μm, which is ¼ wavelength in a vacuum.

A diagram illustrating the step of depositing a metal layer on the insulating layer to fabricate the antenna and other high frequency components of the thermal pixel circuit is shown in FIG. 32. With reference to FIGS. 28 and 32, in a next step, a metal layer is deposited over the insulator 390 forming the antenna 398 (e.g., a patch antenna in this example embodiment), biasing resister R₁ 400, and load (discharge) resister R₂ 402 (step 606). Note that components shown in this fabrication embodiment (e.g., resisters R₁, R₂, C, etc.) correspond to similarly labeled components in FIGS. 2 and 16. Note also that in alternative embodiments, other high frequency (e.g., 30 THz) components such as an antenna array, impedance matching network components, capacitors, resistors, connecting traces, etc. may be fabricated in this or other steps. In particular, in this step, a patch antenna 398 is fabricated along with signal feed 399, resistors 400, 402, and connections 404 (between biasing resister R₁ 400 and ground), 406 (between one end of discharge resister R₂ and V_{CC}) and 408 (between the other end of discharge resister R₂ and V_{CC}).

Note that metal film can be deposited using several well-known deposition techniques, including, but not limited to, evaporation and sputtering. Other techniques are also applicable as well depending on the implementation. It is noted that when selecting the metal, the Drude model is preferably taken into account. The Drude model specifies metal conductance and dispersion properties at terahertz frequencies. Taking the Drude model into account yields, the metals gold and silver are optimum metals for use at terahertz frequencies, while other metals such as aluminum and copper, for example, are also suitable.

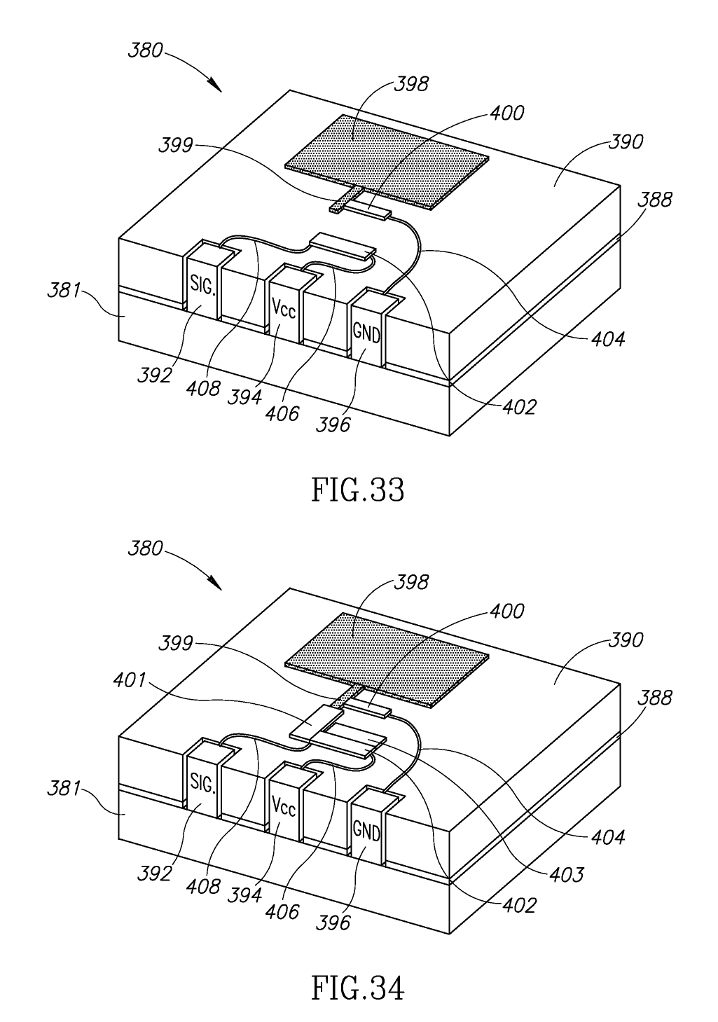

A diagram illustrating the fabrication step of antenna oxidation to create a thin insulating layer is shown in FIG. 33. With reference to FIGS. 28 and 33, in a next step, a thin insulating film (represented by the speckled pattern) is generated over the antenna 398 and signal feed 399 (step 608). Note that when implementing the circuit, although the pattern is shown only on the antenna and feed, since it is difficult to generate a thin layer only in specific areas, the entire top portion of the structure is covered with the thin insulator.

In one embodiment, the insulating material comprises Aluminum Oxide (Al₂O₃), Silicon Dioxide (SiO₂) or other suitable insulators. Note that the thin insulating film can be generated using any well-known technique. For example, it can be generated by oxidizing the metal film deposited in the previous step 606. Oxidation can be performed naturally (i.e. in an oxygen atmosphere) or in water, or by using Atomic Layer Deposition (ALD) to create a very thin layer of insulating material.

A diagram illustrating the fabrication step of additional deposition of metal to create the MIM junction and DC capacitor is shown in FIG. 34. With reference to FIGS. 28 and 34, in a second metallization step, another layer of metallic film is deposited over the insulating layer thus completing the MIM structure 401 and forming capacitor 403 (step 610).

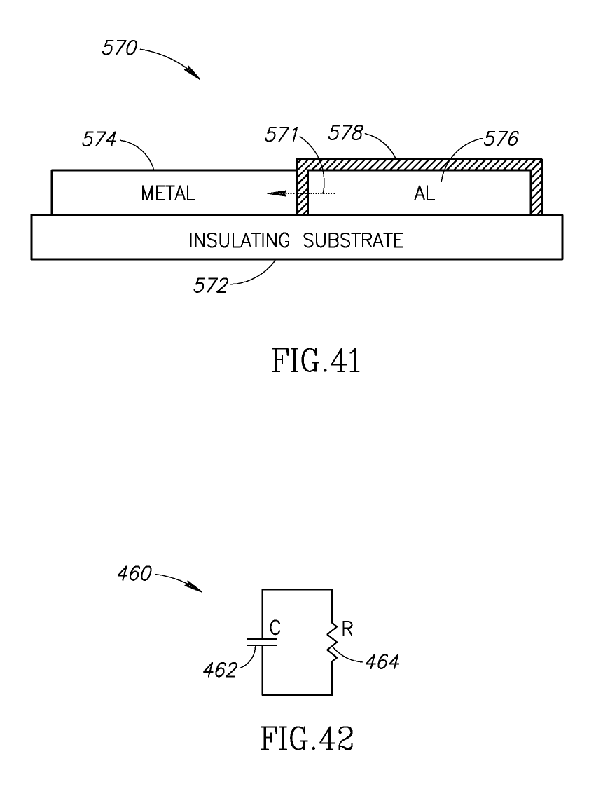

The MIM structure, when complete, is oriented horizontally (as in FIG. 41) and comprises the metal layer 401, oxide (patterned area of the signal feed) and the metal of the signal feed itself. As described supra, the MIM structure functions as the rectifying element to rectify the terahertz signal from the antenna or impedance matching circuit. The capacitor, also oriented horizontally is formed by the two metal elements 401 and 403 with the gap separating the two metal “plates”. This metallization step is similar to the previous step of metallic film deposition performed previously (step 606).

It is noted that, in one embodiment of the invention, the high frequency front end sensor circuit components, i.e. antenna, impedance matching network, rectifier, etc. are fabricated on top of the back end readout circuit components forming a stacked structure. The interface between the two circuits comprising the signal, V_{CC} and ground pads 392, 394, 396, respectively.

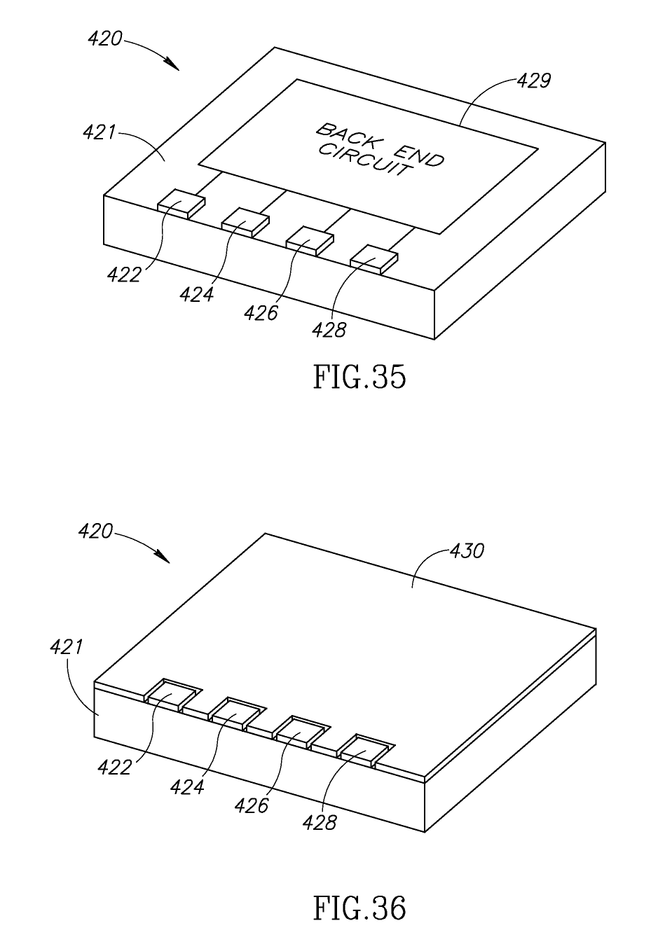

Fabrication of an example balanced pixel circuit is described infra A diagram illustrating a silicon IC wafer with a differential backend readout circuit implemented on it is shown in FIG. 35. With reference to FIGS. 28 and 35, as a first step, the entire backend readout circuit 429 is fabricated on a standard monolithic silicon substrate (wafer) 421 (step 600). At this stage, the pixel circuit, generally referenced 420, comprises a monolithic silicon substrate 421 upon which the backend readout circuit 429 is fabricated using standard IC functions and techniques. The IC wafer can be manufactured using any of the various available processes such as CMOS, BiCMOS, BiPolar, SiGe and others. Each die comprises several functions and blocks as required for the thermal detector to operate. The functions and blocks may comprise, for example, a differential amplifier, trans-impedance amplifier, analog switch for CCD implementation, DC current source, DC voltage source, analog to digital converter (ADC) and other functions depending on the particular implementation. The silicon die also comprises pads 422, 424, 426, 428 to interface the silicon wafer containing the low frequency back end to the metal layers (to be deposited) containing the high frequency front end sensor circuit components. In this balanced pixel circuit example, pads 422, 424, 426, 428 are provided for I_{DC}, I_{OUT-}, I_{OUT+} and V_{CC}, respectively. This corresponds to a pixel circuit having a current sense topology. Note that in the case of a voltage sense topology, pads 422, 424, 426, 428 provide connections for ground, V_{OUT-}, V_{OUT+} and V_{CC}, respectively.

A diagram illustrating the fabrication step of deposition of a thin metal layer on the IC wafer is shown in FIG. 36. With reference to FIGS. 28 and 36, as a next step, a metal layer 430 is deposited on the silicon wafer (step 602). Note that the metal layer is a conducting layer and is adapted to function as an IR reflector (e.g., SWIR, MWIR, LWIR) as described in more detail infra, thus it is preferable that the metal exhibit good conductivity in the IR bands. Examples of such metals include gold, silver, copper and aluminum.

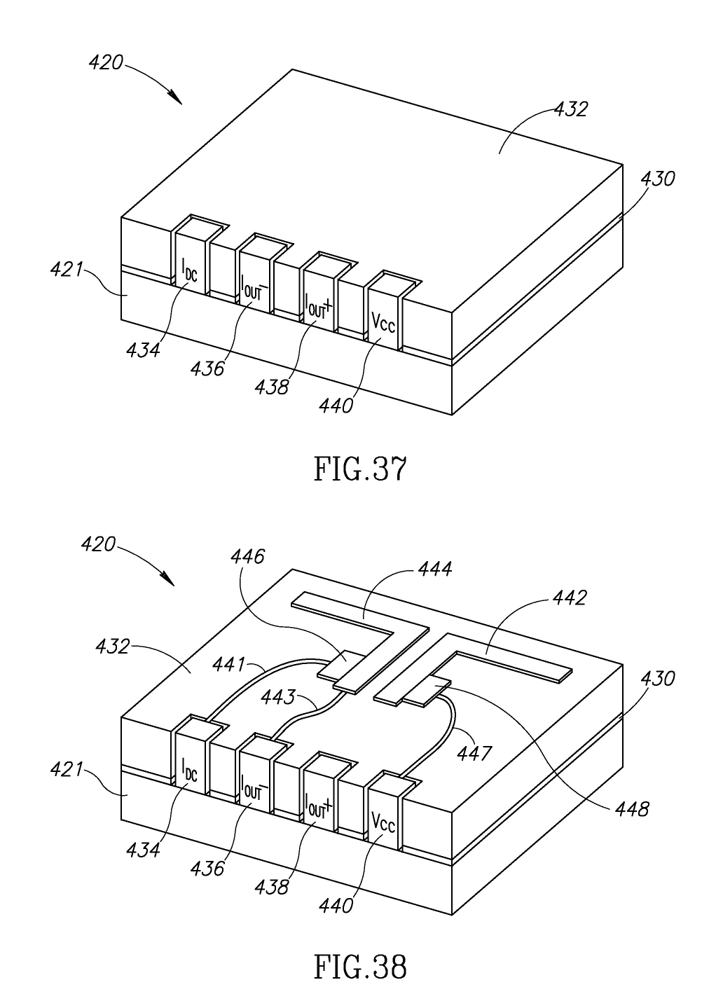

A diagram illustrating the fabrication step of deposition of a thick insulating layer on top of the metal layer is shown in FIG. 37. With reference to FIGS. 28 and 37, in a next step, a relatively thick insulating layer 432 is deposited over the metal layer 430 and the pads 434, 436, 438, 440 for I_{DC}, I_{OUT-}, I_{OUT+} and V_{CC}, respectively, are lengthened (step 604). The insulating layer 432 comprises a thick (e.g., approximately 2 μm to allow electromagnetic waves of 10 μm wavelength to resonate in the insulating layer) insulating layer on top of the metal layer 430. In one embodiment, the insulator 432 comprises silicon dioxide (SiO₂). Alternatively, it comprises any type of insulator that is applicable to the particular IC process, such as aluminum oxide (Al₂O₃), palladium oxide or other insulating materials. The thickness of the insulator is configured such that it presents approximately a ¼ wavelength (in the LWIR band). The insulator layer 432, together with the reflective metal layer 430 below it, function to enhance the gain of the antenna deposited over it. Therefore, configuring the insulator thickness to be approximately ¼ wavelength optimizes the reflective effect. Note that the insulating layer may have thicknesses other than ¼ wavelength depending on the purpose the insulator is to serve. It is noted that preferably the thickness of the insulator is calculated taking into account the refractive index of the insulator material in the band of interest, e.g., SWIR, MWIR, LWIR, etc. For example, assuming the insulator refractive index is greater than one, its thickness will most likely be less than 2.5 μm, which is ¼ wavelength in a vacuum.

A diagram illustrating the step of depositing of a metal layer on the insulating layer to fabricate high frequency differential sensor components is shown in FIG. 38. With reference to FIGS. 28 and 38, in a next step, a metal layer is deposited over the insulator 432 forming the one or more high frequency (e.g., 30 THz) components such as the antenna, antenna array, impedance matching network components, capacitors, resistors, connecting traces, etc. (step 606). In particular, in this step, the antenna with differential interface (symmetrical portions 442, 444) and resistors 446, 448 and connections 441 (connecting resister 446 to the I_{DC} pad), 443 (connecting antenna segment 444 to the I_{OUT-} pad) and 447 (connecting resister 448 to the I_{OUT+} pad) are formed.

Note that metal film can be deposited using several well-known deposition techniques, including, but not limited to, evaporation and sputtering. Other techniques are also applicable as well depending on the implementation. It is noted that when selecting the metal, the Drude model is preferably taken into account. The Drude model specifies metal conductance and dispersion properties at terahertz frequencies. Taking the Drude model into account yields, the metals gold and silver are optimum metals for use at terahertz frequencies, while other metals such as aluminum and copper, for example, are also suitable.

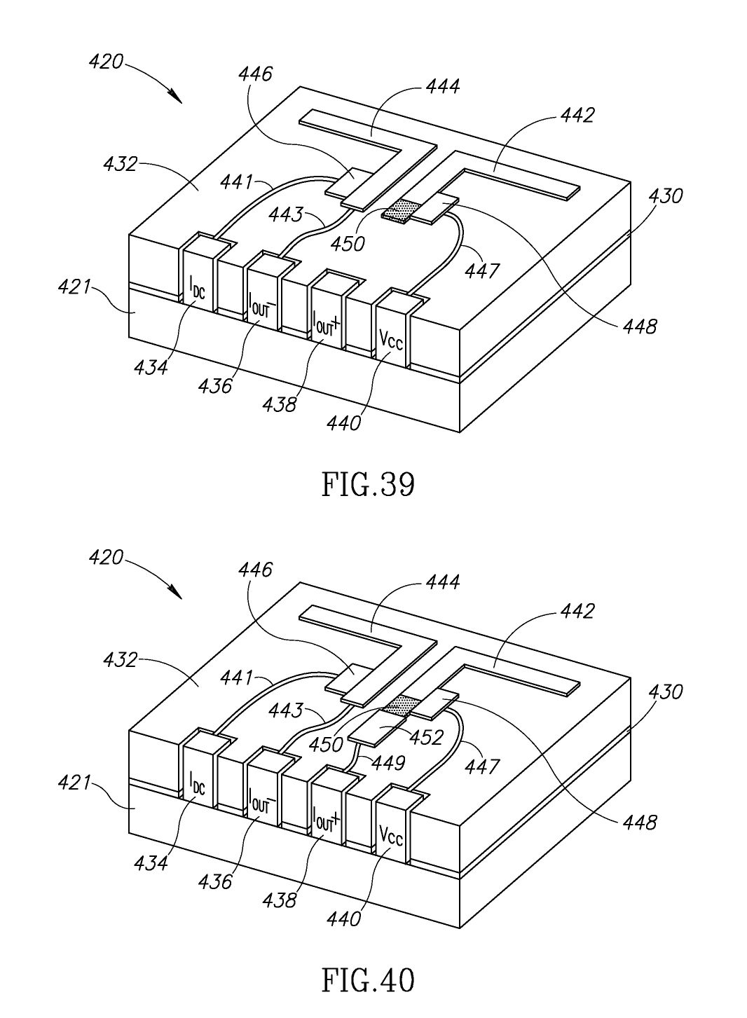

A diagram illustrating the fabrication step of deposition of a thin insulating film layer to build a MIM structure is shown in FIG. 39. With reference to FIGS. 28 and 39, in a next step, a thin insulating film 450 (represented as the patterned area) is generated over a portion of the antenna segment 442 (which was formed during the previous metallization step) (step 608). In one embodiment, the insulating material comprises Aluminum Oxide (Al₂O₃), Silicon Dioxide (SiO₂) or other suitable insulators. Note that the thin insulating film can be generated using any well-known technique. For example, it can be generated by oxidizing the metal film deposited in the previous step 606. Oxidation can be performed naturally (i.e. in an oxygen atmosphere) or in water, or by using Atomic Layer Deposition (ALD) to create a very thin layer of insulating material.

A diagram illustrating the fabrication step of deposition of a second metal layer to complete the MIM structure is shown in FIG. 40. With reference to FIGS. 28 and 40, in a second metallization step, a layer of metallic film 452 is deposited thereby completing the MIM structure (step 610). The MIM structure has a horizontal orientation and comprises the metal of the end portion of antenna segment 442, oxide 450 and metal element 452. Also formed during this step is the remaining connection 449 between pad 438 and the metal layer 452 of the MIM structure. The MIM structure, when complete, functions as the rectifying element to rectify the terahertz signal from the antenna or impedance matching circuit. This second metallization step is very similar to the previous step of metallic film deposition performed previously (step 606).

It is noted that, as in the case of the unbalanced pixel circuit described supra, in one embodiment of the invention, the high frequency front end sensor circuit components, i.e. antenna, impedance matching network, rectifier, etc. are fabricated on top of the back end readout circuit components forming a stacked structure. The interface between the two circuits comprising the ground/I_{DC}, +/−differential output signals and V_{CC}.

The fabrication techniques described supra for both unbalanced and balanced pixel circuits can be extended to construct an array of pixels. Complete 1D (linear), 2D and stereoscopic arrays of thermal sensing pixels can be constructed (as shown in FIGS. 17 and 18 described supra) using well-known semiconductor processes. In one embodiment, such an array can serve as the core of a thermal imaging system. The array of thermal pixels can be fabricated with the low frequency readout circuit operative to interface to a standard CMOS imager.

MIM Structure Based Rectifying Element

The MIM rectifying element used to rectify the signal at terahertz frequencies (e.g., SWIR, MWIR or LWIR signal) from the antenna (or impedance matching circuit if present) will now be described in more detail. As described supra, the output of the antenna (if no impedance matching is used) or the impedance matching circuit (more likely case) is rectified using one or more distributed Metal-Insulator-Metal (MIM) structures.

A diagram illustrating an example metal-insulator-metal (MIM) structure in more detail is shown in FIG. 41. The structure, generally referenced 570, comprises a pair of metal layers 574, 576 separated by a thin insulating layer 578 (e.g., silicon dioxide) and fabricated in a horizontal orientation on an insulating substrate 572. The MIM structure comprises a “sandwich” (vertical or horizontal) of two metals with a very thin insulator between them. The two metals can be identical or they may be different. Since the metals are insulated, there is no ohmic contact between them, thus essentially creating a plate capacitor.

If the insulator is thin enough, current flows through the insulator when voltage is applied between the two metals. The current flowing is due to the well-known quantum effect known as “tunneling”. Note that tunnel current grows exponentially with voltage as shown in the non-linear current-voltage (I-V) curve 220 of FIG. 15.

It can be shown that under certain conditions, MIM structures exhibit exponential I-V curves I∝e^{V}. The I-V curve is due to the tunneling of charges (i.e. electrons) through the thin insulating layer. Current leaks through the insulating layer of the MIM structure by various physical mechanisms the primary one being associated with tunneling. Since tunneling speed is very high the nonlinear I-V curve of MIM structures can be used to rectify very high frequency signals. More specifically, MIM structures can be used to rectify SWIR, MWIR and LWIR band signals.

MIM structures, by definition, however, have very high parasitic capacitance inherent in their structure. This parasitic capacitance is parallel to the nonlinear rectification, and may thus short-circuit the rectification if it exhibits low enough impedance. As an example, consider a MIM structure with an area A of 1 μm² and an insulating layer thickness D of 5 nm. The capacitance of the MIM structure can be calculated as follows:

$$\begin{matrix}C = {ɛ}_{0} \frac{A}{D} \\ \approx 8.85 * {10}^{- 12} \frac{{10}^{- 12}}{5 * {10}^{- 9}} \\ = 1.77 * {10}^{- 15} \\ = 1.77 fF\end{matrix} \qquad ( 4 )$$

The impedance at 30 THz, for example, is thus given by:

$$\begin{matrix}Z = \frac{1}{2 π fC} \\ = \frac{1}{2 π30 * {10}^{12} * 1.77 * {10}^{- 15}} \\ \approx 3 Ω\end{matrix} \qquad ( 5 )$$

A 1 μm² MIM structure therefore exhibits a parasitic capacitance with an impedance equivalent to 3Ω.

A schematic diagram illustrating an example lumped RC model of the MIM junction is shown in FIG. 42. The model, generally referenced 460, comprises a resistor R 464 in parallel with capacitor C 462. The model is a simplified electrical lumped RC model of the MIM structure described supra. The capacitor C represents the parasitic capacitance and the resistor R represents the small-signal equivalent of the tunnel resistance.

Consider, for example, the detection of LWIR energy whose typical wavelength is 10 μm. A MIM structure having typical dimensions of that is with typical dimensions of 1 μm² cannot be considered a lumped element but must be designed and analyzed as a distributed element.

In one embodiment, the MIM element is designed and configured using distributed (as opposed to lumped) synthesis techniques. Using a distributed approach, the reactive (i.e. capacitive and inductive) components of the MIM impedance can be partially or even completely canceled out leaving a pure (or almost pure) resistive load. It is this resistive load that represents the tunneling leakage effect which the pixel sensor circuit uses for rectification of the electrical signal generated by the antenna.

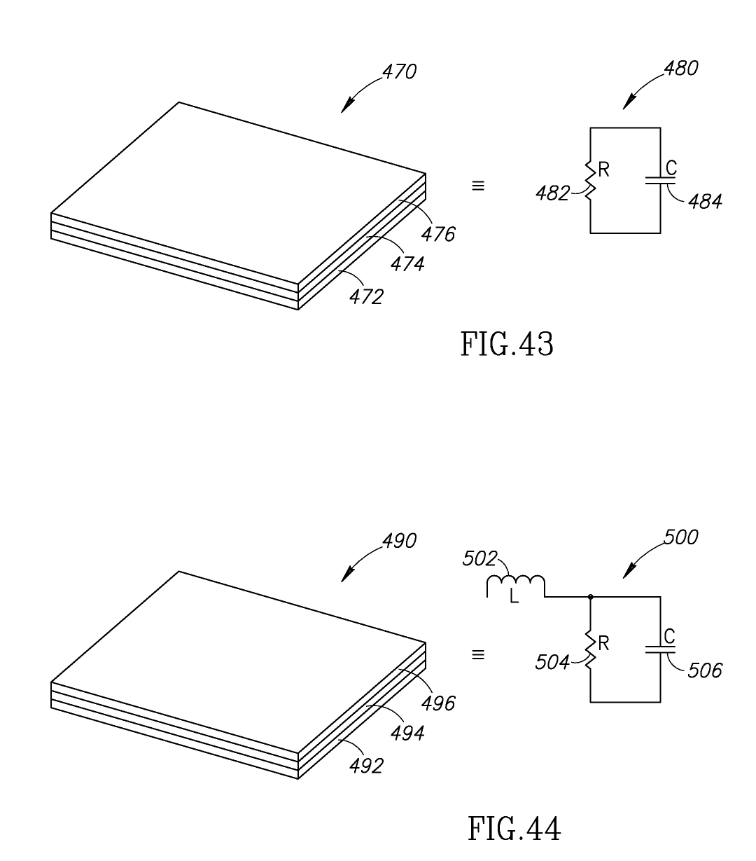

A MIM structure can be modeled as a resistor in parallel with a capacitor, as shown in FIG. 43 where the MIM structure 470 comprises layers 472, 474, 476 and is equivalent to circuit 480 comprising resistor R 482 and capacitor C 484. The capacitance of C is approximately the equivalent capacitance of a simple parallel plate capacitor. The resistor R representing the leakage current due to the tunneling effect. Since the tunneling I-V curve (220 FIG. 15) is exponential, the value of resistance R changes as a function of the DC voltage induced on the MIM structure. The higher the DC voltage, the lower the small-signal resistance.

Note that this lumped element model is accurate only at frequencies where the wavelength of the signal is much smaller than the physical size of the MIM structure. If the size of the MIM structure is of the same order of magnitude as the wavelength of the signal, than the MIM structure must be analyzed as a distributed structure. In other words, the basic MIM element is preferably modeled as a basic building block of a transmission line, as shown in FIG. 44 where the MIM structure 490 comprises layers 492, 494, 496 and is equivalent to circuit 500 comprising inductor 502, resistor R 504 and capacitor C 506.

In accordance with the invention, MIM structures are generated using distributed synthesis techniques where the distributed capacitance and inductance of the MIM structure resonate thus canceling themselves out leaving only the resistive portion (i.e. the rectification). In an alternative embodiment, several L-C pairs are constructed to create a filter having a wide pass band where the filter exhibits pure resistive properties. Typically, distributed inductance (rather than capacitance) is designed into the MIM structure to cancel out the capacitive reactance inherent in the MIM structure leaving a pure or substantially pure rectification function.

In one embodiment, depending on the implementation, DC bias voltage is applied across the MIM structure. A DC bias voltage is used to place the MIM structure at a certain operating point (see I-V curve 220 in FIG. 15). When the MIM structure is excited with an AC signal at terahertz frequencies that is much smaller than the DC voltage, the MIM structure functions as a small-signal diode (i.e. rectifier) effectively rectifying the AC signal. Thus, the MIM structure is a small-signal, application specific ultra-fast rectifier.

It is noted that numerous semiconductor topologies are suitable to implement the MIM structure and pixel circuit of the present invention. Example topologies include, but are not limited to, various transmission line combinations, lumped capacitive and inductive elements, etc. In particular, examples are provided below of a (1) microstrip transmission line; (2) distributed LC resonator; and (3) quarter-wavelength transformer. In each case the MIM structure attempts to (1) minimize or cancel out altogether the reactive elements on the MIM structure; and (2) maintain as wide a bandwidth as possible since the wider the bandwidth, the more energy is rectified by the tunneling small-signal resistor.

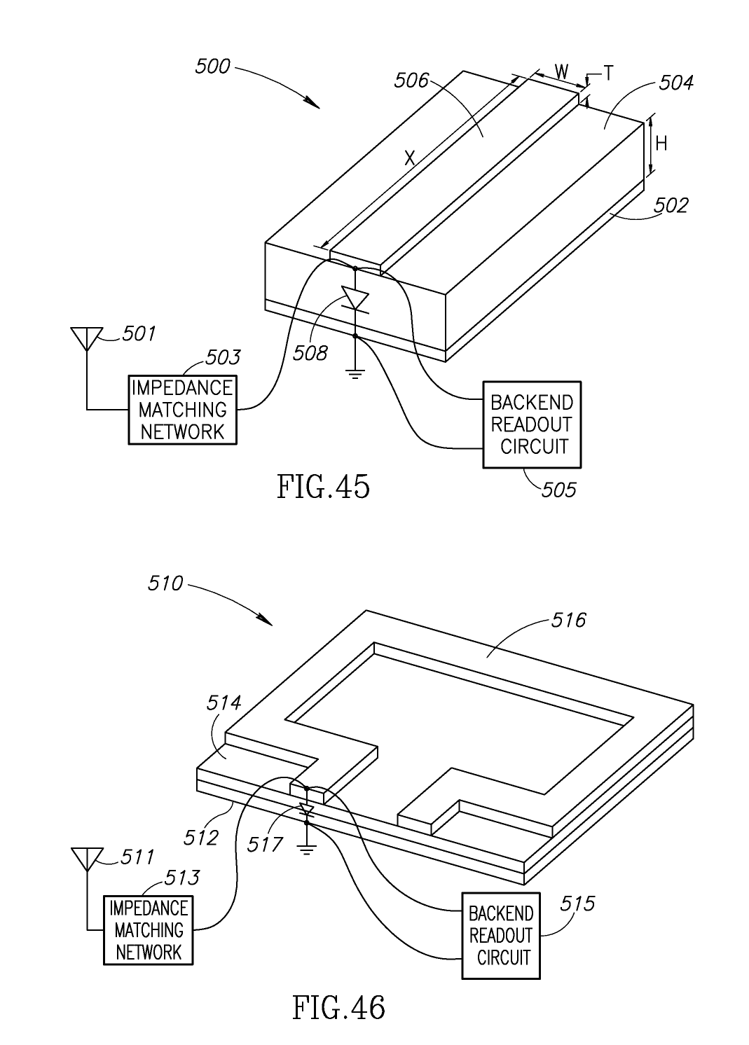

A diagram illustrating an example of a microstrip transmission line is shown in FIG. 45. Well-known in the art, a microstrip transmission line, generally referenced 500, comprises an unbalanced pair of inductors whereby one serves as a ground plane 502 and the other serves as the signal conductor 506 of thickness T, width W and length X, separated by an insulating material 504 having height H. Implementing a MIM microstrip transmission line permits the structure to be analyzed as a lossy transmission line wherein the losses comprise the actual energy being rectified by the MIM structure. A lossy transmission line functions to attenuate the electromagnetic wave as it propagates through the line. The microstrip line exhibits a certain impedance in its ports, whereby the impedance comprises a resistance element. This resistance element represents the losses, i.e. the energy, that are absorbed by the transmission line.

When used in the thermal sensor portion of the pixel circuit of the invention, the MIM microstrip line functions as a rectifying element (as described supra), as indicated in FIG. 45 by diode 508. In one embodiment, the signal conductor 506 receives the signal from the impedance matching network 503 and antenna 501. In an alternative embodiment, if no impedance matching circuit is employed, the signal conductor is connected directly to the antenna. The microstrip line functions to rectify the received signal and convert it to a DC voltage. The diode (i.e. at signal conductor 506) is connected to the backend readout circuit 505. The ground plane 502 is connected to the impedance matching network and the backend readout circuit.

A diagram illustrating a first example of an inductive MIM structure is shown in FIG. 46. The inductive MIM structure, generally referenced 510, comprises a first metal layer 512, thin insulating layer 514 and second metal layer 516. The inductive MIM structure is operative to provide a parallel inductance to partially or completely cancel out the parasitic capacitance inherent in the MIM structure.

The routing of the top metal layer comprises a 1-turn inductor parallel to the MIM parasitic capacitor. The inductance is configured such that the inductance L and capacitance C resonates at the operating frequency (e.g., LWIR). The well-known expression for the resonance is provided below

$$f = \frac{1}{2 π \sqrt{LC}} \qquad ( 6 )$$

Note that this example MIM structure represents a semi-lumped, semi-distributed approach to canceling the inherent capacitance of the MIM structure.

When used in the thermal sensor portion of the pixel circuit of the invention, the inductive MIM structure functions as a rectifying element (as described supra), as indicated in FIG. 46 by diode 517. In one embodiment, the top metal layer 516 receives the signal from the impedance matching network 513 and antenna 511. In an alternative embodiment, if no impedance matching circuit is employed, the signal conductor is connected directly to the antenna. The inductive MIM structure functions to rectify the received signal and convert it to a DC voltage. The diode (i.e. at top metal layer 516) is connected to the backend readout circuit 515. The bottom metal layer 512, electrical ground, is connected to the impedance matching network and the backend readout circuit.

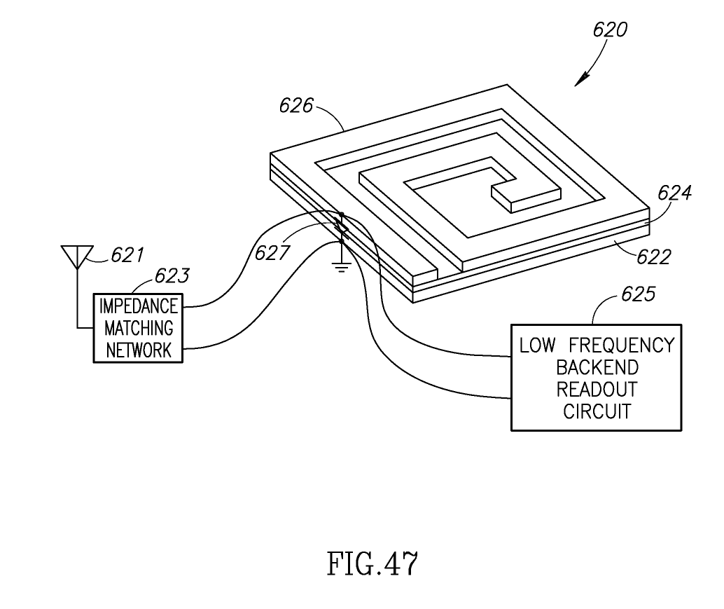

A diagram illustrating a second example inductive MIM structure having a spiral shape is shown in FIG. 47. The inductive MIM structure, generally referenced 620 comprises a first metal layer 622, thin insulating layer 624 and second metal layer 626 in the shape of a spiral. The inductive MIM structure is operative to provide a parallel inductance to partially or completely cancel out the parasitic capacitance inherent in the MIM structure.

When used in the thermal sensor portion of the pixel circuit of the invention, the inductive MIM structure functions as a rectifying element (as described supra), as indicated in FIG. 47 by diode 627. In one embodiment, the top metal layer 626 receives the signal from the impedance matching network 623 and antenna 621. In an alternative embodiment, if no impedance matching circuit is employed, the signal conductor is connected directly to the antenna. The inductive MIM structure functions to rectify the received signal and convert it to a DC voltage. The diode (i.e. at top metal layer 626) is connected to the backend readout circuit 625. The bottom metal layer 622, electrical ground, is connected to the impedance matching network and the backend readout circuit.

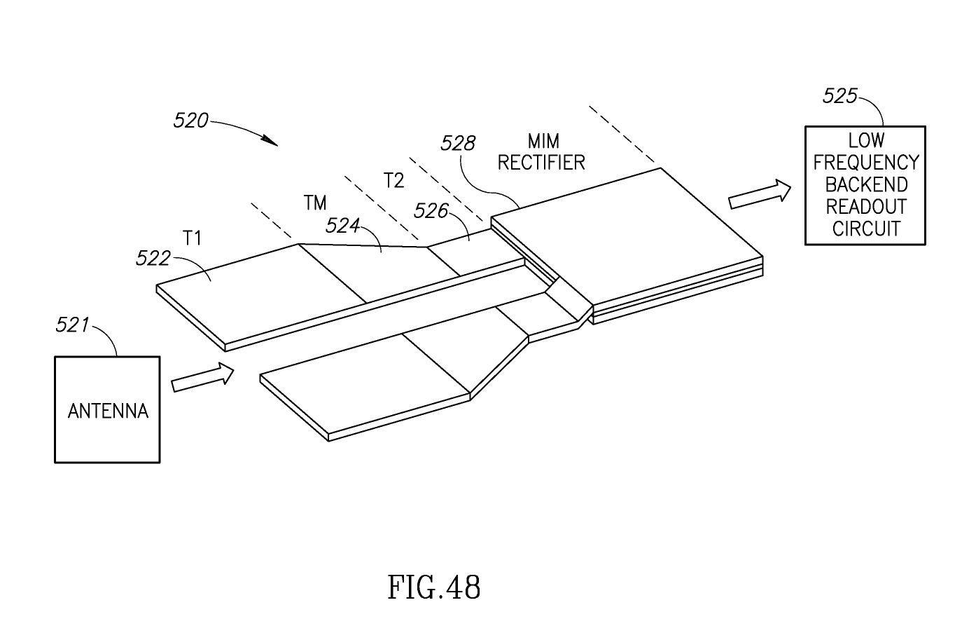

A diagram illustrating an example two step quarter wavelength transformer is shown in FIG. 48. A quarter-wavelength transformer, well known circuit in the RF electrical arts, uses a waveguide as an impedance transformer. Assuming the waveguide has impedance Z₀, and is exactly ¼ wavelength long, it reflects an input impedance Zᵢₙ onto an output impedance Zₒᵤₜ as shown in the expression below:

$${Z}_{out} = \frac{{Z}_{o}^{2}}{{Z}_{in}} \qquad ( 7 )$$

Note that several quarter-wavelength transformers can be combined in series resulting in a very wideband impedance transformer. The circuit of FIG. 48, generally referenced 520, is an example of a two-step quarter wavelength transformer and comprises transformer T1 522 configured to receive the signal from the antenna 521 and transformer T2 526. A matching transformer TM 524 functions to prevent reflections between transformers T1 and T2. The impedance at the right side of the structure is the MIM structure 528. The two-step transformer functions to convert the capacitive impedance of the MIM structure into an inductive impedance. This acts to effectively cancel the reactance of the MIM structure leaving the rectifier and pure resistance. The rectified signal output of the MIM structure is amplified and processed further by backend readout circuit 525. Note that the waveguide topology in this example embodiment is differential. It is appreciated that other waveguide topologies such as microstrip, stripline and co-planar waveguide may also be used to implement quarter-wavelength transformers. Note also that in this example, the thickness of the layers is approximately 50 nm. In general, the thickness of the layers is preferably thicker than the skin effect depth which depends on frequency (e.g., 14 nm at 30 THz). The metal used to construct the layers may comprise any suitable metal, such as gold, silver, aluminum, copper, etc.

As described supra, the MIM structure is constructed using two metal layers where the metals used may be the same or different. Using two different metals with different work functions creates a MIM structure with a very strong “distortion” around zero bias. This distortion is actually electrons tunneling from the high work function metal to the low work function metal. This tunneling occurs, however, with no biasing voltage applied and is due to the inherent tendency towards the lowest thermodynamic equilibrium. When this occurs, a steady-state electric field is created across the insulator. This field functions to encourage tunneling in one direction, and interfere with tunneling in the other direction. Thus, in an alternative embodiment, a MIM structure is constructed of two different metals that is operative to rectify with zero bias. This significantly reduces the power requirements for a resultant pixel circuit and pixel array since there is no need for the DC biasing of each pixel.

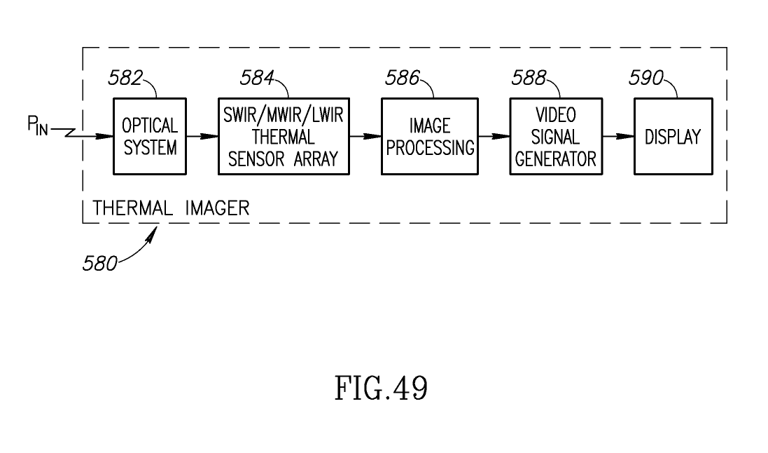

A high level block diagram illustrating an example thermal imaging camera device is shown in FIG. 49. Using the pixel circuit of the invention, a thermal imager system, generally referenced 580, is constructed. The thermal imager 580 comprises an optical system, a thermal sensor array 584, image processing circuitry 586, video signal generator 588 and display 590.

In operation, the optical system functions to focus the SWIR, MWIR or LWIR energy onto the thermal sensor array. The thermal sensor array may comprise a 1D, 2D or stereoscopic array as described in detail supra. The thermal sensor array functions to convert the black body radiation absorbed by the antenna (tuned to appropriate band SWIR, MWIR or LWIR) into an electrical signal that can be processed by the image processing circuit. The output of the image processing block is converted into a video signal by the video signal generator for presentation on the display at suitable video frame rates (e.g., 30 to 60 Hz).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. As numerous modifications and changes will readily occur to those skilled in the art, it is intended that the invention not be limited to the limited number of embodiments described herein. Accordingly, it will be appreciated that all suitable variations, modifications and equivalents may be resorted to, falling within the spirit and scope of the present invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A metal-insulator-metal (MIM) structure for terahertz detection in a thermal sensor, comprising:
a first metal layer fabricated on a monolithic semiconductor substrate;
an insulator layer fabricated over said first metal layer;
a second metal layer fabricated over said insulator layer;
wherein said insulator layer is sufficiently thin for tunneling to occur between said first metal layer and second metal layer; and
wherein as a result of said tunneling, said MIM structure functions as a rectifier when excited with an input signal at terahertz frequencies so as to generate a rectified signal therefrom.

2. The MIM structure according to claim 1, wherein said first metal layer and said second metal layer comprise the same metal.

3. The MIM structure according to claim 1, wherein said first metal layer and said second metal layer comprise different metals exhibiting different work functions thereby creating a MIM structure operative to rectify said input signal at zero bias.

4. The MIM structure according to claim 3, wherein said MIM structure exhibits a steady state electric field across said insulator layer at zero bias that aids tunneling in one direction of current flow and interferes with tunneling in the other direction thereby creating a non-linear I-V curve at zero bias.

5. The MIM structure according to claim 1, further comprising a DC bias circuitry thereby placing said MIM structure at a particular operating point.

6. The MIM structure according to claim 1, wherein the dimensions, topologies and configuration of said MIM structure are determined using distributed design techniques.

7. The MIM structure according to claim 1, wherein the dimensions and configuration of said MIM structure are determined using distributed design techniques such that the reactance of said MIM structure is at least partially canceled out in its operative frequency band.

8. The MIM structure according to claim 1, wherein said MIM structure comprises a microstrip transmission line.

9. The MIM structure according to claim 1, wherein said MIM structure comprises an LC resonator whereby said second metal layer is configured as an inductance in parallel with a parasitic capacitance of said MIM structure.

10. The MIM structure according to claim 1, wherein said second metal layer is configured as a spiral whose distributed inductance is operative to at least partially cancel the parasitic capacitance of said MIM structure.

11. The MIM structure according to claim 1, further comprising a quarter wavelength transformer whose inductance is operative to cancel the parasitic reactance of said MIM structure.

12. The MIM structure according to claim 11, wherein said quarter wavelength transformer comprises a plurality of transformers connected in series.

13. A thermal sensor adapted to be fabricated on a monolithic semiconductor substrate, comprising:
an antenna element operative to absorb black body radiation at terahertz (THz) frequencies and convert it to an electrical signal;
an impedance matching circuit coupled to said antenna element;
a metal-insulator-metal (MIM) structure operative to rectify the output of said impedance matching network; and
wherein said MIM structure comprises a first metal layer, an insulator layer fabricated over said first metal layer, a second metal layer fabricated over said insulator layer, wherein said insulator layer is sufficiently thin for tunneling to occur between said first metal layer and second metal layer, and wherein as a result of said tunneling, said MIM structure functions as a rectifier when excited with the terahertz frequency output of said impedance matching network so as to generate a rectified signal therefrom.

14. The thermal sensor according to claim 13, wherein said first metal layer and said second metal layer comprise the same metal.

15. The thermal sensor according to claim 13, wherein said first metal layer and said second metal layer comprise different metals exhibiting different work functions thereby creating a MIM structure operative to rectify the output of said impedance matching network at zero bias.

16. The thermal sensor according to claim 13, further comprising a DC bias circuitry thereby placing said MIM structure at a particular operating point.

17. The thermal sensor according to claim 13, wherein the dimensions, topologies and configuration of said MIM structure are determined using distributed design techniques.

18. The thermal sensor according to claim 13, wherein the dimensions and configuration of said MIM structure are determined using distributed design techniques such that the reactance of said MIM structure is at least partially canceled out.

19. The thermal sensor according to claim 13, wherein said MIM structure comprises a microstrip transmission line.

20. The thermal sensor according to claim 13, wherein said MIM structure comprises an LC resonator whereby said second metal layer is configured as an inductance in parallel with a parasitic capacitance of said MIM structure.

21. The thermal sensor according to claim 13, wherein said second metal layer is configured as a spiral whose distributed inductance is operative to at least partially cancel the parasitic capacitance of said MIM structure.

22. The thermal sensor according to claim 13, further comprising a quarter wavelength transformer whose inductance is operative to cancel the parasitic reactance of said MIM structure.

23. A method of constructing a thermal sensor on a monolithic semiconductor substrate, said method comprising:
fabricating an antenna element on said substrate, said antenna element operative to absorb black body radiation at terahertz (THz) frequencies and convert it to an electrical signal;
fabricating a first metal layer of a metal-insulator-metal (MIM) structure on said substrate;
fabricating an insulating layer over said first metal layer;
fabricating a second metal layer over said insulating layer;
wherein said insulator layer is fabricated sufficiently thin for tunneling to occur between said first metal layer and second metal layer such that said MIM structure functions as a rectifier when excited with terahertz frequency energy absorbed by said antenna and to generate a rectified signal therefrom; and
wherein said MIM structure is configured and shaped using distributed design techniques such that a first distributed reactance is generated that at least partially cancels out a second distributed reactance inherent in said MIM structure.

24. A thermal imager, comprising:
an antenna element operative to absorb black body radiation at terahertz (THz) frequencies and convert it to an electrical signal; and
an impedance matching circuit coupled to said antenna element, said impedance matching circuit operative to match the complex impedance of said antenna element to a high impedance load;
a metal-insulator-metal (MIM) structure coupled to said load, said MIM structure operative to perform non-coherent rectification of the signal generated by said antenna element;
a sense circuit coupled to said MIM structure, said sense circuit operative to generate a single pixel measurement of the black body radiation power absorbed by said antenna element and
a display subsystem operative to present to a user information corresponding to said single pixel measurement.

25. The thermal imager according to claim 24, wherein said MIM structure comprises a first metal layer, an insulator layer fabricated over said first metal layer, a second metal layer fabricated over said insulator layer, wherein said insulator layer is sufficiently thin for tunneling to occur between said first metal layer and second metal layer, and wherein as a result of said tunneling, said MIM structure functions as a rectifier when excited with the terahertz frequency output of said impedance matching network so as to generate a rectified signal therefrom.
